(19) United States
(12) Patent Application Publication
(10) Pub. No.: US 2025/0185369 A1
(43) Pub. Date: Jun. 5, 2025

(54) DISPLAY DEVICE

(71) Applicant: Samsung Display Co., LTD., Yongin-si (KR)

(72) Inventor: Jong Hyun CHOI, Yongin-si (KR)

(21) Appl. No.: 18/806,436

(22) Filed: Aug. 15, 2024

(30) Foreign Application Priority Data
Dec. 5, 2023 (KR) 10-2023-0174169

(51) Int. Cl. H01L 27/12; G09G 3/32; H01L 25/075

(52) U.S. Cl. CPC H10D 86/60; G09G 3/32; H01L 25/0753; H10D 86/431; H10D 86/441; G09G 2300/0426; G09G 2300/043

(57) ABSTRACT

Provided is a display device. The display device includes a substrate including a display area in which emission areas are arranged, and a non-display area, a circuit layer, and an element layer, and including light-emitting elements respectively located in the emission areas. The circuit layer includes data lines, a first bypass auxiliary line extending in a first direction, and electrically connected to a first data line adjacent to the non-display area in the first direction, a second bypass auxiliary line extending in a second direction, paired with a second data line spaced further apart from the non-display area than the first data line in the first direction, and electrically connected to the first bypass auxiliary line, and a gate initialization voltage line extending in the first direction. Two first bypass auxiliary lines adjacent to each other in the second direction are located adjacent to the gate initialization voltage line.

### CROSS-REFERENCE TO RELATED APPLICATION

The present application claims priority to, and the benefit of, Korean Patent Application No. 10-2023-0174169, filed on Dec. 5, 2023, in the Korean Intellectual Property Office, the entire disclosure of which is incorporated herein by reference.

### BACKGROUND

### 1. Technical Field

The present disclosure relates to a display device.

### 2. Description of the Related Art

With the advance of information-oriented society, more and more demands are placed on display devices for displaying images in various ways. For example, display devices are employed in various electronic devices, such as smartphones, digital cameras, laptop computers, navigation devices, and smart televisions.

The display device may be a flat panel display device, such as a liquid crystal display device, a field emission display device, or a light-emitting display device. Examples of the light-emitting display device may include an organic light-emitting display device including organic light-emitting elements, an inorganic light-emitting display device including inorganic light-emitting elements, such as inorganic semiconductors, or a micro light-emitting display device including micro light-emitting elements.

The organic light-emitting display device displays an image using light-emitting elements, each including a light-emitting layer made of an organic light-emitting material. As described above, the organic light-emitting display device implements image display using a self-light-emitting element, and thus may have relatively superior performance in power consumption, response speed, luminous efficiency, luminance, and wide viewing angle compared to other display devices.

One surface of the display device may be a display surface including a display area in which an image is displayed, and a non-display area that is a periphery of the display area. Emission areas, which are for emitting light with respective luminances and colors, may be arranged in the display area.

### SUMMARY

An electronic device equipped with the display device may include optical sensors, such as a camera, an illumination sensor, and a distance sensor.

When the optical sensors are located below the display surface of the display device, the optical sensors may overlap the non-display area of the display device to secure the optical path of the optical sensors. In this case, there is a problem that the width of the non-display area increases due to the arrangement of the optical sensors.

To solve this problem, a portion of the display area of the display device may include both an emission area and a light-transmitting area, and the optical sensors may overlap a portion of the display area. In this case, due to the arrangement of the light-transmitting area, a portion of the display area that overlaps the optical sensors has a lower resolution than the remaining portion thereof, so there may be a problem that the display quality may be degraded.

In view of the above, aspects of the present disclosure provide a display device that may reduce or prevent degradation of display quality even when a portion of a display area overlaps optical sensors.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a substrate including a display area having emission areas, and a non-display area around the display area, an element layer above the substrate, and including light-emitting elements respectively in the emission areas, and a circuit layer between the substrate and the element layer, and including light-emitting pixel drivers respectively electrically connected to the light-emitting elements, arranged side by side with each other in a first direction and in a second direction, and including a first light-emitting pixel driver and a second light-emitting pixel driver adjacent to each other in the second direction, data lines extending in the second direction for transmitting data signals to the light-emitting pixel drivers, two first bypass auxiliary lines extending in the first direction, adjacent to each other in the second direction, and respectively electrically connected to two first data lines of the data lines that are adjacent to the non-display area, a second bypass auxiliary line extending in the second direction, electrically connected to the first bypass auxiliary line, and paired with a second data line of the data lines that is spaced further from the non-display area than the first data line in the first direction, and a gate initialization voltage line adjacent to one of the first bypass auxiliary lines in the second direction at a boundary between the first light-emitting pixel driver and the second light-emitting pixel driver, and extending in the first direction for transmitting a gate initialization voltage to the light-emitting pixel drivers.

The first light-emitting pixel driver and the second light-emitting pixel driver may be electrically connected to the gate initialization voltage line.

The display device may further include a display-driving circuit for transmitting the data signals to the data lines, wherein the circuit layer further includes data supply lines in the non-display area, and electrically connected between the data lines and the display-driving circuit, wherein a bypass area on one side of the display area includes a bypass middle area, a first bypass side area parallel to the bypass middle area in the first direction and in contact with the non-display area, and a second bypass side area between the bypass middle area and the first bypass side area, wherein the first data lines are in the first bypass side area, wherein the second data line is in the second bypass side area, wherein a first data supply line of the data supply lines is electrically connected to one of the first data lines through one of the first bypass auxiliary lines and the second bypass auxiliary line, and wherein a second data supply line of the data supply lines is directly electrically connected to the second data line.

The circuit layer may further include a bias voltage line extending in the first direction for transmitting a bias voltage to the light-emitting pixel drivers, wherein the light-emitting pixel drivers further include a third light-emitting pixel driver adjacent to the second light-emitting pixel driver in the second direction, and wherein the second light-emitting pixel driver and the third light-emitting pixel driver are electrically connected to the bias voltage line adjacent to a boundary between the second light-emitting pixel driver and the third light-emitting pixel driver.

The light-emitting pixel drivers may further include a fourth light-emitting pixel driver adjacent to the first light-emitting pixel driver in the first direction, a fifth light-emitting pixel driver adjacent to the second light-emitting pixel driver in the first direction, and a sixth light-emitting pixel driver adjacent to the third light-emitting pixel driver in the first direction, wherein the fourth light-emitting pixel driver and the fifth light-emitting pixel driver are electrically connected to the gate initialization voltage line, and wherein the bias voltage line includes a first main extension portion extending in the first direction, and a bypass portion connected to the first main extension portion, and bypassing a light-transmitting area including contact points at which the second light-emitting pixel driver, the third light-emitting pixel driver, the fifth light-emitting pixel driver, and the sixth light-emitting pixel driver contact each other in the display area.

The circuit layer may have a multi-layer structure including a first semiconductor layer above the substrate, a first gate-insulating layer covering the first semiconductor layer, a first gate conductive layer above the first gate-insulating layer, a second gate-insulating layer covering the first gate conductive layer, a second gate conductive layer above the second gate-insulating layer, a first interlayer insulating layer covering the second gate conductive layer, a second semiconductor layer above the first interlayer insulating layer, a third gate-insulating layer covering the second semiconductor layer, a third gate conductive layer above the third gate-insulating layer, a second interlayer insulating layer covering the third gate conductive layer, a first source-drain conductive layer above the second interlayer insulating layer, a first planarization layer covering the first source-drain conductive layer, a second source-drain conductive layer above the first planarization layer, and a second planarization layer covering the second source-drain conductive layer, wherein the first semiconductor layer and the second semiconductor layer in the first light-emitting pixel driver are symmetrical with the first semiconductor layer and the second semiconductor layer in the second light-emitting pixel driver with respect to the boundary between the first light-emitting pixel driver and the second light-emitting pixel driver.

The first semiconductor layer and the second semiconductor layer in the first light-emitting pixel driver may be symmetrical with the first semiconductor layer and the second semiconductor layer in the third light-emitting pixel driver with respect to a boundary between the first light-emitting pixel driver and the third light-emitting pixel driver.

The light-emitting pixel drivers may include a first transistor electrically connected between a first node and a second node, a pixel capacitor electrically connected between a first power line for transmitting a first power and a third node, a second transistor electrically connected between a respective one of the data lines and the first node, a third transistor electrically connected between the second node and the third node, a fourth transistor electrically connected between the gate initialization voltage line and the third node, a fifth transistor electrically connected between the first power line and the first node, a sixth transistor electrically connected between the second node and a fourth node, a seventh transistor electrically connected between an anode initialization voltage line for transmitting an anode initialization voltage and the fourth node, and an eighth transistor electrically connected between the bias voltage line and the first node, wherein the first node is electrically connected to a first electrode of the first transistor, wherein the second node is electrically connected to a second electrode of the first transistor, wherein the third node is electrically connected to a gate electrode of the first transistor, wherein the fourth node is electrically connected to one of the light-emitting elements, wherein the first transistor, the second transistor, the third transistor, the fourth transistor, the fifth transistor, the sixth transistor, the seventh transistor, and the eighth transistor include a gate electrode, a channel portion overlapping the gate electrode, and a first electrode portion and a second electrode portion connected to respective sides of the channel portion, wherein the third transistor and the fourth transistor further includes an auxiliary gate electrode overlapping the gate electrode and the channel portion, wherein the first semiconductor layer includes a channel portion, a first electrode portion, and a second electrode portion of the first transistor, the second transistor, the fifth transistor, the sixth transistor, the seventh transistor, and the eighth transistor, and wherein the second semiconductor layer includes a channel portion, a first electrode portion, and a second electrode portion of the third transistor and the fourth transistor.

The channel portion of the first transistor of the first light-emitting pixel driver may be substantially identical to the channel portion of the first transistor of the second light-emitting pixel driver.

The third transistor may be configured to be turned on by a gate control signal of a gate control line, wherein the fourth transistor is configured to be turned on by a scan initialization signal of a scan initialization line, wherein the fifth transistor and the sixth transistor are configured to be turned on by an emission control signal of an emission control line, and wherein the seventh transistor is configured to be turned on by a bias control signal of a bias control line, wherein the first light-emitting pixel driver and the second light-emitting pixel driver share at least one of the gate initialization voltage line, the scan initialization line, or the gate control line, and wherein the second light-emitting pixel driver and the third light-emitting pixel driver share at least one of the anode initialization voltage line, the bias control line, or the emission control line.

The second gate conductive layer may include the gate initialization voltage line, wherein the second semiconductor layer further includes an auxiliary electrode portion connected to the second electrode portion of the fourth transistor, and extending in the first direction, wherein the first source-drain conductive layer includes the first bypass auxiliary line, wherein the auxiliary electrode portion of the first light-emitting pixel driver and the auxiliary electrode portion of the second light-emitting pixel driver are connected to each other, and electrically connected to the gate initialization voltage line through a gate initialization connection electrode, and wherein the two first bypass auxiliary lines adjacent to the boundary between the first light-emitting pixel driver and the second light-emitting pixel driver overlaps at least one of the auxiliary electrode portion of the first light-emitting pixel driver or the auxiliary electrode portion of the second light-emitting pixel driver.

One of two second bypass auxiliary lines adjacent to the boundary between the first light-emitting pixel driver and the second light-emitting pixel driver may be adjacent to one side of the gate initialization voltage line in the second direction, wherein another of the two second bypass auxiliary lines is adjacent to another side of the gate initialization voltage line in the second direction.

Two second bypass auxiliary lines adjacent to the boundary between the first light-emitting pixel driver and the second light-emitting pixel driver may be arranged side by side on one side of the gate initialization voltage line in the second direction.

According to an aspect of the present disclosure, there is provided a display device including a substrate including a display area having emission areas, and a non-display area around the display area, an element layer above the substrate, and including light-emitting elements respectively in the emission areas, and a circuit layer between the substrate and the element layer, and including light-emitting pixel drivers respectively electrically connected to the light-emitting elements of the element layer, arranged side by side with each other in a first direction and a second direction, and including a first transistor for generating a driving current of the light-emitting element, data lines extending in the second direction for transmitting data signals to the light-emitting pixel drivers, a first bypass auxiliary line extending in the first direction, and electrically connected to a first data line of the data lines that is adjacent to the non-display area in the first direction, a second bypass auxiliary line extending in the second direction, paired with a second data line of the data lines that is spaced further from the non-display area than the first data line in the first direction, and electrically connected to the first bypass auxiliary line, and a first power line for transmitting a first power to the light-emitting pixel drivers, and including a first power main line extending in the first direction, overlapping a gate electrode of the first transistor, and overlapping the first bypass auxiliary line, and a first power sub-line extending in the second direction and electrically connected to the first power main line.

The light-emitting pixel drivers may include a first light-emitting pixel driver, a second light-emitting pixel driver, and a third light-emitting pixel driver arranged in the second direction, wherein the first light-emitting pixel driver and the second light-emitting pixel driver are electrically connected to a gate initialization voltage line adjacent to a boundary between the first light-emitting pixel driver and the second light-emitting pixel driver, and wherein the second light-emitting pixel driver and the third light-emitting pixel driver are electrically connected to a bias voltage line adjacent to a boundary between the second light-emitting pixel driver and the third light-emitting pixel driver.

The light-emitting pixel drivers may further include a fourth light-emitting pixel driver adjacent to the first light-emitting pixel driver in the first direction, a fifth light-emitting pixel driver adjacent to the second light-emitting pixel driver in the first direction, and a sixth light-emitting pixel driver adjacent to the third light-emitting pixel driver in the first direction, wherein the fourth light-emitting pixel driver and the fifth light-emitting pixel driver are electrically connected to the gate initialization voltage line, and wherein the bias voltage line includes a first main extension portion extending in the first direction, and a bypass portion connected to the first main extension portion, and bypassing a light-transmitting area including contact points at which the second light-emitting pixel driver, the third light-emitting pixel driver, the fifth light-emitting pixel driver, and the sixth light-emitting pixel driver contact each other in the display area.

The circuit layer may have a multi-layer structure including a first semiconductor layer above the substrate, a first gate-insulating layer covering the first semiconductor layer, a first gate conductive layer above the first gate-insulating layer, a second gate-insulating layer covering the first gate conductive layer, a second gate conductive layer above the second gate-insulating layer, a first interlayer insulating layer covering the second gate conductive layer, a second semiconductor layer above the first interlayer insulating layer, a third gate-insulating layer covering the second semiconductor layer, a third gate conductive layer above the third gate-insulating layer, a second interlayer insulating layer covering the third gate conductive layer, a first source-drain conductive layer above the second interlayer insulating layer, a first planarization layer covering the first source-drain conductive layer, a second source-drain conductive layer above the first planarization layer, and a second planarization layer covering the second source-drain conductive layer, wherein the first transistor is electrically connected between a first node and a second node.

The light-emitting pixel drivers may further include a pixel capacitor electrically connected between the first power line and a third node, a second transistor electrically connected between one of the data lines and the first node, a third transistor electrically connected between the second node and the third node, a fourth transistor electrically connected between the gate initialization voltage line and the third node, a fifth transistor electrically connected between the first power line and the first node, a sixth transistor electrically connected between the second node and a fourth node, a seventh transistor electrically connected between an anode initialization voltage line for transmitting an anode initialization voltage and the fourth node, and an eighth transistor electrically connected between the bias voltage line and the first node, wherein the first node is electrically connected to a first electrode of the first transistor, wherein the second node is electrically connected to a second electrode of the first transistor, wherein the third node is electrically connected to a gate electrode of the first transistor, wherein the fourth node is electrically connected to one of the light-emitting elements, wherein the first transistor, the second transistor, the third transistor, the fourth transistor, the fifth transistor, the sixth transistor, the seventh transistor, and the eighth transistor include a gate electrode, a channel portion overlapping the gate electrode, and a first electrode portion and a second electrode portion connected to respective sides of the channel portion, wherein the third transistor and the fourth transistor further includes an auxiliary gate electrode overlapping the gate electrode and the channel portion, wherein the first semiconductor layer includes a channel portion, a first electrode portion, and a second electrode portion of the first transistor, the second transistor, the fifth transistor, the sixth transistor, the seventh transistor, and the eighth transistor, and wherein the second semiconductor layer includes a channel portion, a first electrode portion, and a second electrode portion of the third transistor and the fourth transistor.

The third transistor may be configured to be turned on by a gate control signal of a gate control line, wherein the fourth transistor is configured to be turned on by a scan initialization signal of a scan initialization line, wherein the fifth transistor and the sixth transistor are configured to be turned on by an emission control signal of an emission control line, wherein the seventh transistor is configured to be turned on by a bias control signal of a bias control line, wherein the first light-emitting pixel driver and the second light-emitting pixel driver share at least one of the gate initialization voltage line, the scan initialization line, or the gate control line, and wherein the second light-emitting pixel driver and the third light-emitting pixel driver share at least one of the anode initialization voltage line, the bias control line, or the emission control line.

The second gate conductive layer may include the first power main line, wherein the first source-drain conductive layer includes the first bypass auxiliary line, and a first power connection line electrically connected to the first power main line and the first power sub-line, and spaced apart from the first bypass auxiliary line, and wherein the second source-drain conductive layer includes the first power sub-line.

However, aspects according to the embodiments of the present disclosure are not limited to those exemplified above and various other effects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a perspective view showing an electronic device according to embodiments;

FIG. 2 is an exploded perspective view showing the electronic device of FIG. 1;

FIG. 3 is a plan view illustrating the display device of FIG. 2;

FIG. 4 is a cross-sectional view taken along the line A-A′ of FIG. 3;

FIG. 5 is a layout diagram illustrating part B of FIG. 3;

FIG. 6 is an equivalent circuit diagram showing the light-emitting pixel driver of FIG. 5;

FIG. 7 is a plan view showing the substrate of FIG. 4;

FIG. 8 is a layout diagram illustrating the circuit layer of part C of FIG. 7;

FIG. 9 is a layout diagram illustrating the circuit layer of part D of FIG. 7;

FIG. 10 is a cross-sectional view taken along the line F-F′ of FIG. 8;

FIG. 11 is a layout diagram illustrating part E of FIG. 7;

FIG. 12 is a plan view showing the circuit layer of part G of FIG. 11 according to one or more embodiments;

FIG. 13 is a plan view showing the first source-drain conductive layer, the second semiconductor layer, the third gate conductive layer, the second gate conductive layer, and the first gate conductive layer of FIG. 12;

FIG. 14 is a cross-sectional view taken along the line J-J′ of FIG. 12;

FIG. 15 is a plan view showing the first source-drain conductive layer, the second semiconductor layer, the third gate conductive layer, the second gate conductive layer, and the first gate conductive layer in the circuit layer of part G of FIG. 11 according to one or more embodiments;

FIG. 16 is a plan view showing the first source-drain conductive layer, the second semiconductor layer, the third gate conductive layer, the second gate conductive layer, and the first gate conductive layer in the circuit layer of part G of FIG. 11 according to one or more embodiments;

FIG. 17 is a plan view showing the circuit layer of part H of FIG. 11 according to one or more embodiments;

FIG. 18 is a plan view showing the first source-drain conductive layer, the second semiconductor layer, the third gate conductive layer, the second gate conductive layer, and the first gate conductive layer of FIG. 17;

FIG. 19 is a plan view showing the circuit layer of part I of FIG. 11 according to one or more embodiments;

FIG. 20 is a plan view showing the first semiconductor layer, the first gate conductive layer, and the bias voltage line of FIG. 19;

FIG. 21 is a cross-sectional view taken along the line K-K′ of FIG. 19;

FIG. 22 is a plan view showing part I of FIG. 11 according to one or more embodiments;

FIG. 23 is a plan view showing part I of FIG. 11 according to one or more embodiments;

FIG. 24 is a plan view showing part I of FIG. 11 according to one or more embodiments;

FIG. 25 is a plan view showing part l′ of FIG. 11 according to one or more embodiments;

FIG. 26 is a plan view showing a first semiconductor layer, a second semiconductor layer, a first gate conductive layer, a second gate conductive layer, and a third gate conductive layer in part G of FIG. 11 according to one or more embodiments;

FIG. 27 is a plan view showing a first semiconductor layer, a second semiconductor layer, a first gate conductive layer, a second gate conductive layer, and a third gate conductive layer in part G of FIG. 11 according to one or more embodiments;

FIG. 28 is a plan view showing a first semiconductor layer, a second semiconductor layer, a first gate conductive layer, a second gate conductive layer, and a third gate conductive layer in part G of FIG. 11 according to one or more embodiments;

FIG. 29 is a plan view showing a first semiconductor layer and a second semiconductor layer of each of a first light-emitting pixel driver, a second light-emitting pixel driver, a fourth light-emitting pixel driver, and a fifth light-emitting pixel driver according to embodiments; and

FIG. 30 is a plan view showing a first semiconductor layer and a second semiconductor layer of each of a first light-emitting pixel driver, a second light-emitting pixel driver, a fourth light-emitting pixel driver, and a fifth light-emitting pixel driver according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, specific embodiments will be described with reference to the accompanying drawings.

The display device according to embodiments may include a substrate, a circuit layer, and an element layer. The substrate includes a display area in which emission areas are arranged, and a non-display area located around the display area. The element layer is located on the circuit layer, and includes light-emitting elements respectively located in the emission areas.

The circuit layer may include light-emitting pixel drivers respectively electrically connected to the light-emitting elements of the element layer and arranged side by side with each other in first and second directions, a data line extending in the second direction and transmitting a data signal to the light-emitting pixel drivers, a first bypass auxiliary line extending in the first direction and electrically connected to a first data line adjacent to the non-display area in the first direction, a second bypass auxiliary line extending in the second direction, paired with a second data line spaced further apart than the first data line, and electrically connected to the first bypass auxiliary line, and a gate initialization voltage line extending in the first direction and transmitting a gate initialization voltage to the light-emitting pixel drivers.

According to one or more embodiments, the second bypass auxiliary line is adjacent to the gate initialization voltage line in the second direction.

In this way, the data signal of the first data line transmitted through the second bypass auxiliary line may be shielded by the gate initialization voltage of the gate initialization voltage line. As a result, the distortion of the signal applied to the gate electrode of a transistor through wires adjacent to the second bypass auxiliary line and extending in the first direction due to poor coupling with the data signal of the second bypass auxiliary line may be reduced.

According to embodiments, the circuit layer may further include data supply lines located in the non-display area, and electrically connected between the data lines and the display-driving circuit. Among the data supply lines, a first data supply line transmitting a data signal of the first data line may be electrically connected to the first data line through the first bypass auxiliary line and the second bypass auxiliary line. Among the data supply lines, a second data supply line transmitting a data signal of the second data line may be directly electrically connected to the second data line.

In this way, because the first data supply line does not extend to a portion of the non-display area adjacent to the bent edge of the substrate, the extension length of the data supply lines may be reduced, thereby reducing the width of the non-display area.

According to embodiments, the light-emitting pixel drivers may include a first light-emitting pixel driver, a second light-emitting pixel driver, and a third light-emitting pixel driver arranged side by side in the second direction.

The first light-emitting pixel driver and the second light-emitting pixel driver may be electrically connected to one gate initialization voltage line located adjacent to a boundary between the first light-emitting pixel driver and the second light-emitting pixel driver.

According to embodiments, the circuit layer may further include a bias voltage line extending in the first direction and transmitting a bias voltage to the light-emitting pixel drivers.

The second light-emitting pixel driver and the third light-emitting pixel driver may be electrically connected to one bias voltage line located adjacent to a boundary between the second light-emitting pixel driver and the third light-emitting pixel driver.

In this way, the number of gate initialization voltage lines and the number of bias voltage lines may be reduced, so that a portion of the display area between the second light-emitting pixel driver and the third light-emitting pixel driver may be provided as a light-transmitting area in which no conductive layers are located.

That is, even if the number of light-emitting pixel drivers is not reduced, a light-transmitting area for the optical path of the optical sensors may be provided. Accordingly, even if a portion of the display area overlaps the optical sensors, degradation of display quality may be reduced or prevented.

In addition, according to embodiments, the light-emitting pixel drivers may further include a fifth light-emitting pixel driver and a sixth light-emitting pixel driver adjacent to the second light-emitting pixel driver and the third light-emitting pixel driver, respectively, in the first direction.

One bias voltage line located adjacent to the boundary between the second light-emitting pixel driver and the third light-emitting pixel driver may include a first main extension portion extending in the first direction, and a bypass portion connected to the first main extension portion and bypassing the light-transmitting area including contact points at which the second, third, fifth, and sixth light-emitting pixel drivers contact each other.

That is, according to embodiments, one bias voltage line may include the bypass portion that bypasses the light-transmitting area, rather than extending in a straight line in the first direction, so that a larger light-transmitting area may be obtained.

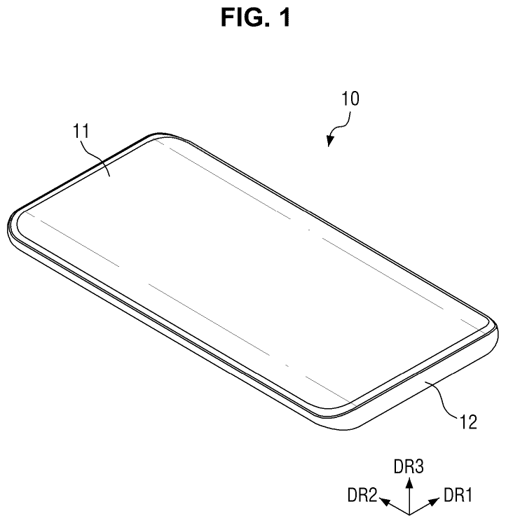

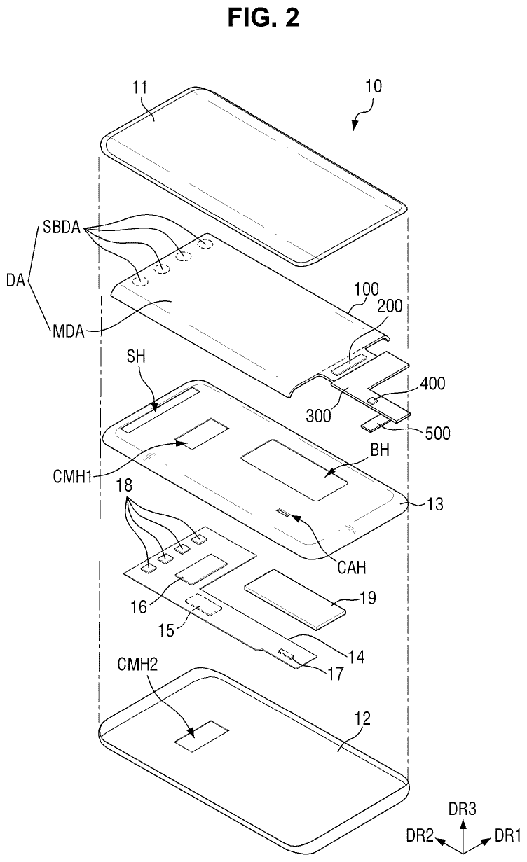

FIG. 1 is a perspective view showing an electronic device according to embodiments. FIG. 2 is an exploded perspective view showing the electronic device of FIG. 1.

Referring to FIG. 1, an electronic device 10 according to embodiments is a device having a function of displaying an image in a display area. The electronic device 10 may provide portability. For example, the electronic device 10 may be a portable electronic device, such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

However, the electronic device 10 according to embodiments is not limited to a portable electronic device, and may be a large-sized device, such as a television, a laptop computer, a monitor, a billboard, and an Internet-of-Things (IoT) device.

The electronic device 10 may include a cover window 11 and a lower cover 12 provided as a housing for protecting a display device 100 (see FIG. 2).

Referring to FIG. 2, the electronic device 10 according to embodiments may further include the display device 100, a bracket 13, at least one optical device 18, and a main circuit board 14 accommodated between the cover window 11 and the lower cover 12.

Hereinafter, a first direction DR1 may be a direction parallel to the short side of the electronic device 10 in plan view, that is, a widthwise direction of the electronic device 10. A second direction DR2 may be a direction parallel to the long side of the electronic device 10 in plan view, that is, a lengthwise direction of the electronic device 10. The third direction DR3 may be a thickness direction of the electronic device 10.

The electronic device 10 may have a rectangular shape in plan view. For example, the electronic device 10 may have a rectangular shape, in plan view, having a short side in the first direction DR1 and a long side in the second direction DR2. A corner where the short side in the first direction DR1 and the long side in the second direction DR2 meet may be right-angled or rounded with a curvature (e.g., predetermined curvature). The planar shape of the electronic device 10 is not limited to the rectangular shape, and may be formed in another polygonal shape, a circular shape or an elliptical shape.

The electronic device 10 may include a display surface on which a display area DA where an image display is implemented is located.

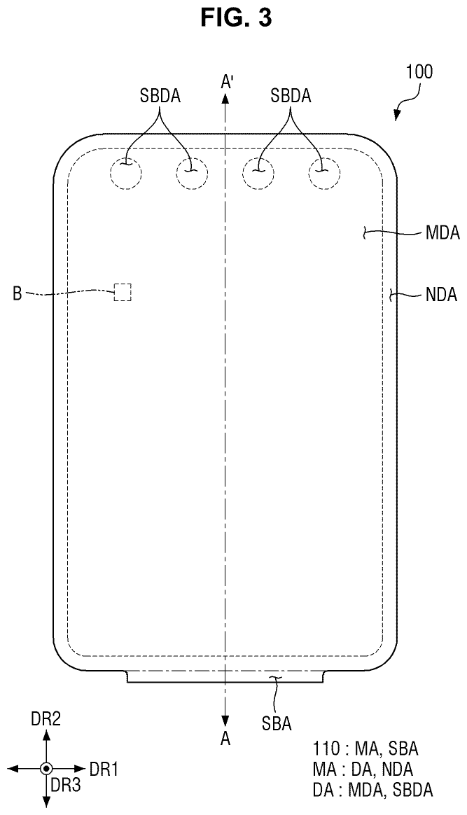

The display device 100 may include the display area DA that emits light to the display surface of the electronic device 10, and a non-display area NDA located around the display area DA. In addition, the display device 100 may further include a sub-region SBA (see FIG. 3) protruding from a portion of the non-display area NDA adjacent to one short side edge of the display area DA.

The display device 100 may further include a display-driving circuit 200 located in the sub-region SBA, a display circuit board 300 fastened to the edge of the sub-region SBA, a touch-driving circuit 400 mounted on the display circuit board 300, and a cable 500 extending from one side of the display circuit board 300.

The display area DA may include a main display area MDA located in most of the display area DA, and at least one sub-display area SBDA surrounded by the main display area MDA and overlapping at least one optical device 18.

The cover window 11 may be located on the display device 100. Accordingly, one surface of the display device 100 through which light is emitted may be covered with the cover window 11.

In other words, the cover window 11 may serve to protect the top surface of the display device 100.

The cover window 11 may include a light-transmitting portion that is transparent, and a light-blocking portion that is opaque.

The light-transmitting portion may overlap the display area DA of the display device 100 in the third direction DR3, and the light-blocking portion may overlap the non-display area NDA of the display device 100 in the third direction DR3.

The cover window 11 may include a top surface portion forming the top surface of the electronic device 10, a left side portion forming the left side surface of the electronic device 10, and a right side portion forming the right side surface of the electronic device 10. The left surface portion of the cover window 11 may extend from the left side of the top surface portion, and the right surface portion thereof may extend from the right side of the top surface portion.

Each of the top, left, and right surface portions of the cover window 11 may include the light-transmitting portion and the light-blocking portion.

The light-transmitting portion of the cover window 11 may be located on most of each of the top, left, and right surface portions of the cover window 11.

The light-blocking portion of the cover window 11 may be located at the upper edge and lower edge of the top surface portion of the cover window 11, at the upper edge, left edge, and lower edge of the left surface portion of the cover window 11, and at the upper edge, right edge, and lower edge of the right surface portion of the cover window 11.

The bracket 13 may be located under the display device 100. The bracket 13 may include plastic, metal, or both plastic and metal. The bracket 13 may include a first camera hole CMH1 into which a camera 16 is inserted, a battery hole BH for holding a battery 19, a light transmission hole SH into which the at least one optical device 18 is inserted, and a cable hole CAH serving as a passage of the cable 500 connected to the display circuit board 300.

The main circuit board 14 and the battery 19 may be located under the bracket 13. The main circuit board 14 may be a printed circuit board or a flexible printed circuit board.

A main processor 15, the camera 16, a main connector 17, and the at least one optical device 18 may be mounted on the main circuit board 14.

The camera 16 may be located on both the top surface and the bottom surface of the main circuit board 14, the main processor 15 may be located on the top surface of the main circuit board 14, and the main connector 17 may be located on the bottom surface of the main circuit board 14.

The main processor 15 may control all functions of the electronic device 10. For example, the main processor 15 may output digital video data to the display-driving circuit 200 through the display circuit board 300 such that the display device 100 displays an image. In addition, the main processor 15 may receive touch data including user's touch coordinates from the touch-driving circuit 400, may determine whether the user (e.g., the user's hand or stylus) has touched or approached, and then may perform an operation corresponding to the user's touch input or approach input. For example, the main processor 15 may perform an operation or execute an application indicated by an icon touched by the user.

The main processor 15 may be an application processor formed of an integrated circuit, a central processing unit, or a system chip.

The camera 16 may process an image frame of a still image or video obtained by an image sensor in a camera mode and output it to the main processor 15.

A cable 500 having passed through the cable hole CAH of the bracket 13 may be connected to the main connector 17. Thus, the main circuit board 14 may be electrically connected to the display circuit board 300.

At least one optical device 18 may include a proximity sensor, an illumination sensor, an iris sensor, a second camera sensor, or the like. The optical device 18, such as a proximity sensor, an illumination sensor, an iris sensor, or a second camera sensor, may be located on the top surface of the main circuit board 14 and in the light transmission hole SH of the bracket 13.

The proximity sensor may detect an object approaching the front surface of the electronic device 10. The proximity sensor may include a light source that outputs light, and a light receiver that receives light reflected by an object. The proximity sensor may generate a sensing signal corresponding to the amount of light reflected by the object, and presence or absence of an object near the front surface of the electronic device 10 may be determined based on the sensing signal of the proximity sensor.

The illuminance sensor may detect the brightness of the front surface of the electronic device 10. The illuminance sensor may include a resistor whose resistance value changes according to the brightness of the incident light.

The iris sensor is a sensor for imaging the user's iris. It can be verified whether the user is a pre-registered user based on whether the image captured by the iris sensor is the same as an iris image previously stored in a memory.

The second camera sensor may process an image frame of a still image or of video obtained by the image sensor and output it to the main processor 710. The second camera sensor may be a complementary metal-oxide-semiconductor (CMOS) image sensor or a charge-coupled device (CCD) sensor. The number of pixels of the second camera sensor may be less than the number of pixels of a first camera sensor 720, and the size of the second camera sensor may be smaller than the size of the first camera sensor 720.

The battery 19 may be spaced apart from the main circuit board 14. That is, the battery 19 might not overlap the main circuit board 14 in the third direction DR3. The battery 19 may be located in, or may overlap, the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The lower cover 12 may be located below the main circuit board 14 and the battery 19. The lower cover 12 may be fixed by being fastened to the bracket 13. The lower cover 12 may form the upper side surface, the lower side surface, and the bottom surface of the electronic device 10. The lower cover 12 may include plastic, metal, or both plastic and metal.

The lower cover 12 may include a second camera hole CMH2 through which the bottom surface of the camera 16 is exposed.

However, the locations of the light transmission hole SH, the first camera hole CMH1, and the second camera hole CMH2 are not limited to those shown in FIG. 2.

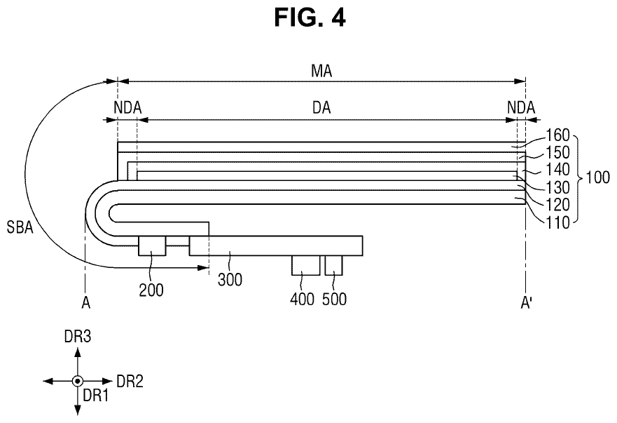

FIG. 3 is a plan view illustrating the display device of FIG. 2. FIG. 4 is a cross-sectional view taken along the line A-A′ of FIG. 3.

A substrate 110 of the display device 100 may include the display area DA and the non-display area NDA located on the display surface, and the sub-region SBA protruding from one side of the non-display area NDA.

The display area DA may be located on most of the display surface. The display area DA may be generally located at the center of the display surface.

The display area DA may include the main display area MDA located in most of the display area DA, and the at least one sub-display area SBDA surrounded by the main display area MDA.

The at least one sub-display area SBDA may overlap the at least one optical device 18 (see FIG. 2).

The non-display area NDA may be located outside the display area DA. The non-display area NDA may be an edge area of the display surface.

The sub-region SBA may protrude in the second direction DR2 from a portion of the non-display area NDA adjacent to the short side of the display area DA.

Because a portion of the sub-region SBA may be transformed in a bent shape, another portion of the sub-region SBA may overlap the display area DA and the non-display area NDA in the third direction DR3.

The display device 100 may include a top surface portion facing the top surface portion of the cover window 11, a left side portion facing the left side portion of the cover window 11, and a right side portion facing the right side portion of the cover window 11. The left surface portion of the display device 100 may extend from the left side of the top surface portion, and the right surface portion of the display device 100 may extend from the right side of the top surface portion.

Each of the top, left, and right surface portions of the display device 100 may include the display area DA and the non-display area NDA.

The display area DA may be located on most of each of the top, left, and right surface portions of the display device 100.

The non-display area NDA may be located at the edge of a main region MA to surround the display area DA (e.g., in plan view).

The sub-region SBA may be a region protruding from the non-display area NDA of the main region MA to one side in the second direction DR2.

Because a part of the sub-region SBA is transformed into a bent shape, another part of the sub-region SBA may be located on the rear surface of the display device 100.

FIGS. 3 and 4 illustrate the display device 100 with a part of the sub-region SBA in a bent state.

Referring to FIG. 4, the display device 100 according to embodiments includes the substrate 110, a circuit layer 120 located on the substrate 110, and an element layer 130 located on the circuit layer 120 (as used herein, “located on” may mean “above”). The display device 100 may further include an encapsulation layer 140 located on the element layer 130, and a touch sensor layer 150 located on the encapsulation layer 140. Also, the display device 100 according to embodiments may further include a polarization layer 160 located on the touch sensor layer 150 to reduce reflection of external light.

The substrate 110 may be formed of an insulating material, such as a polymer resin. For example, the substrate 110 may be formed of polyimide. The substrate 110 may be a flexible substrate which can be bent, folded or rolled. Alternatively, the substrate 110 may be formed of an insulating material, such as glass or the like. The substrate 110 may include the main region MA and the sub-region SBA. The main region MA may include the display area DA and the non-display area NDA.

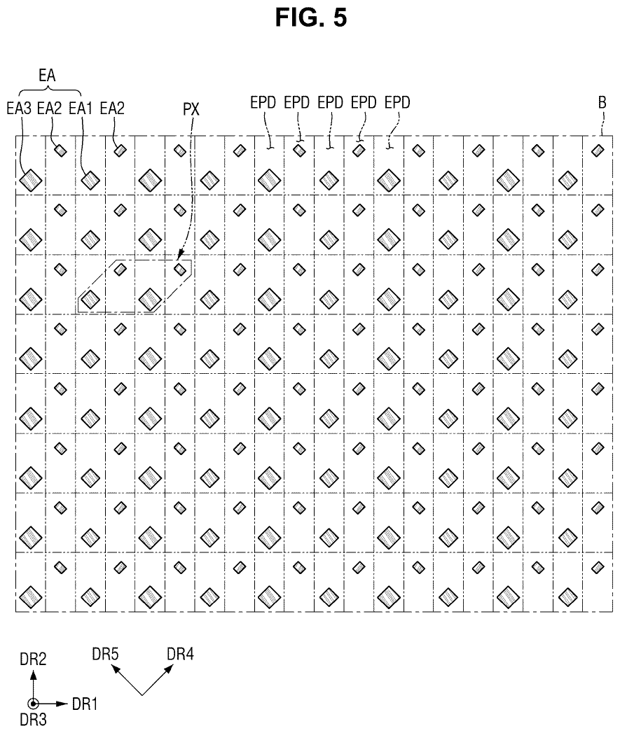

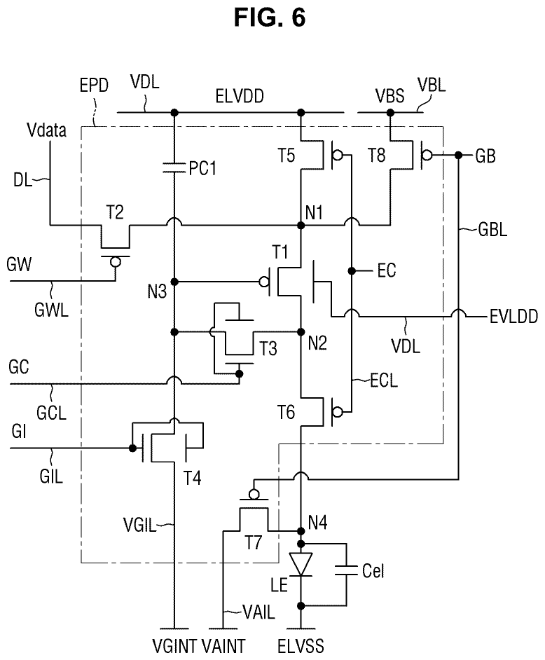

The circuit layer 120 may include light-emitting pixel drivers EPD (see FIG. 5) electrically connected to light-emitting elements LE (see FIG. 6) of the element layer 130, respectively.

The element layer 130 may include light-emitting elements LE respectively located in the emission areas EA.

The encapsulation layer 140 may cover the element layer 130, and may extend into the non-display area NDA to contact the circuit layer 120. The encapsulation layer 140 may include a structure in which two or more inorganic layers and at least one organic layer are alternately stacked.

The touch sensor layer 150 may be located on the encapsulation layer 140, and may correspond to the main region MA. The touch sensor layer 150 may include touch electrodes for sensing a touch of a person or an object.

The polarization layer 160 blocks external light reflected from the touch sensor layer 150, the encapsulation layer 140, the element layer 130, and the circuit layer 120, and the interfaces thereof, which may reduce or prevent the deterioration of visibility of an image due to external light reflection.

The cover window 11 of the electronic device 10 may be located on the polarization layer 160. The cover window 11 may be attached to the polarization layer 160 by a transparent adhesive member, such as an optically clear adhesive (OCA) film or an optically clear resin (OCR). The cover window 11 may be made of an inorganic material, such as glass, or an organic material, such as plastic or a polymer material. Due to the cover window 11, the touch sensor layer 150, the encapsulation layer 140, the element layer 130, and the circuit layer 120 may be protected from electrical and physical impact on the display surface.

FIG. 5 is a layout diagram illustrating part B of FIG. 3.

Referring to FIG. 5, the display area DA of the display device 100 according to embodiments may include the emission areas EA. In addition, the display area DA may further include a non-emission area located in a gap between the emission areas EA.

The light-emitting pixel drivers EPD respectively corresponding to the emission areas EA may be arranged in the display area DA in parallel with each other in the first direction DR1 and in the second direction DR2. The light-emitting pixel drivers EPD may be respectively electrically connected to light-emitting elements LE (see FIG. 5) of the element layer 130 respectively located in the emission areas EA.

The emission areas EA may have a rhombus shape or a rectangular shape in plan view. However, this is only an example, and the planar shape of the emission areas EA according to one or more embodiments is not limited to that illustrated in FIG. 5. That is, in plan view, the emission areas EA may have a polygonal shape, such as a square, a pentagon, a hexagon, etc., or may have a circular or elliptical shape including the edge of a curve.

The emission areas EA may include first emission areas EA1 for emitting light of a first color in a wavelength band (e.g., predetermined wavelength band), second emission areas EA2 for emitting light of a second color in a wavelength band that is lower than that of the first color, and third emission areas EA3 for emitting light of a third color in a wavelength band that is lower than that of the second color.

For example, the first color may be red having a wavelength band of approximately 600 nm to approximately 750 nm. The second color may be green having a wavelength band of approximately 480 nm to approximately 560 nm. The third color may be blue having a wavelength band of approximately 370 nm to approximately 460 nm.

The first emission areas EA1 and the third emission areas EA3 may be alternately arranged in at least one of the first direction DR1 or the second direction DR2.

The second emission areas EA2 may be arranged side by side with each other in at least one of the first direction DR1 or the second direction DR2.

In addition, the second emission areas EA2 may be adjacent to the first emission areas EA1 and the third emission areas EA3 in diagonal directions DR4 and DR5 intersecting the first direction DR1 and the second direction DR2.

Pixels PX displaying their own luminances and colors may be provided by the first emission area EA1, the second emission area EA2, and the third emission area EA3 adjacent to each other among these emission areas EA. In other words, the pixels PX may be a basic unit for displaying various colors including white with a luminance (e.g., predetermined luminance).

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

FIG. 6 is an equivalent circuit diagram showing the light-emitting pixel driver of FIG. 5.

Referring to FIG. 6, one of the light-emitting elements LE of the element layer 130 may be electrically connected between one of the light-emitting pixel drivers EPD of the circuit layer 120 and a second power ELVSS.

That is, the anode electrode of the light-emitting element LE is electrically connected to the light-emitting pixel driver EPD, and the cathode electrode of the light-emitting element LE may be applied with the second power ELVSS that is lower than a first power ELVDD.

A capacitor Cel connected in parallel with the light-emitting element LE refers to a parasitic capacitance between the anode electrode and the cathode electrode. The circuit layer 120 may further include a first power line VDL for transmitting the first power ELVDD, a gate initialization voltage line VGIL for transmitting a gate initialization voltage VGINT, an anode initialization voltage line VAIL for transmitting an anode initialization voltage VAINT, and a bias voltage line VBL for transmitting a bias voltage VBS.

The circuit layer 120 may further include a scan write line GWL for transmitting a scan write signal GW, a scan initialization line GIL for transmitting a scan initialization signal GI, an emission control line ECL for transmitting an emission control signal EC, a gate control line GCL for transmitting a gate control signal GC, and a bias control line GBL for transmitting a bias control signal GB.

One light-emitting pixel driver EPD of the circuit layer 120 may include a first transistor T1 configured to generate a driving current for driving the light-emitting element LE, two or more transistors T2, T3, T4, T5, T6, T7, and T8 electrically connected to the first transistor T1, and at least one capacitor PC1.

The first transistor T1 is connected in series with the light-emitting element LE between the first power ELVDD and the second power ELVSS.

The first transistor T1 may be electrically connected between the first node N1 and the second node N2. The first node N1 is electrically connected to the first electrode (e.g., source electrode) of the first transistor T1. The second node N2 is electrically connected to the second electrode (e.g., drain electrode) of the first transistor T1.

In other words, the first electrode (e.g., the source electrode) of the first transistor T1 may be electrically connected to the first power line VDL through the fifth transistor T5. Further, the second electrode (e.g., the drain electrode) of the first transistor T1 may be electrically connected to the anode electrode of the light-emitting element LE through the sixth transistor T6.

The first pixel capacitor PC1 may be electrically connected between the first power line VDL and a third node N3. The third node N3 is electrically connected to the gate electrode of the first transistor T1. That is, the gate electrode of the first transistor T1 may be electrically connected to the first power line VDL through the first pixel capacitor PC1. Accordingly, the potential of the gate electrode of the first transistor T1 may be maintained at the voltage charged in the first pixel capacitor PC1.

The second transistor T2 may be electrically connected between the data line DL and the first node N1. In other words, the second transistor T2 may be electrically connected between the first electrode of the first transistor T1 and the data line DL. The second transistor T2 may be turned on by the scan write signal GW of the scan write line GWL. That is, the first electrode of the first transistor T1 may be electrically connected to the data line DL through the second transistor T2.

The fifth transistor T5 may be electrically connected between the first node N1 and the first power line VDL. That is, the fifth transistor T5 may be electrically connected between the first electrode of the first transistor T1 and the first power line VDL.

The sixth transistor T6 may be electrically connected between the second node N2 and the fourth node N4. The fourth node N4 is electrically connected to the anode electrode of the light-emitting element LE. The sixth transistor T6 may be electrically connected between the second electrode of the first transistor T1 and the anode electrode of the light-emitting element LE.

The fifth transistor T5 and the sixth transistor T6 may be turned on by the emission control signal EC of the emission control line ECL.

When a data signal Vdata of the data line DL is transmitted to the first electrode of the first transistor T1 through the turned-on second transistor T2, the voltage difference between the gate electrode of the first transistor T1 and the first electrode of the first transistor T1 may be a difference voltage between the first power ELVDD and the data signal Vdata.

In this case, when the voltage difference between the gate electrode of the first transistor T1 and the first electrode of the first transistor T1 (e.g., the gate-to-source voltage difference) becomes equal to or greater than a threshold voltage, the first transistor T1 may be turned on, thereby generating a drain-source current of the first transistor T1 corresponding to the data signal Vdata.

Then, when the fifth transistor T5 and the sixth transistor T6 are turned on, the first transistor T1 may be connected in series with the light-emitting element LE between the first power line VDL and a second power line VSL. Accordingly, the drain-source current of the first transistor T1 corresponding to the data signal Vdata may be supplied as a driving current of the light-emitting element LE. Accordingly, the light-emitting element LE may emit light having a luminance corresponding to the data signal Vdata.

The third transistor T3 may be electrically connected between the second node N2 and the third node N3. That is, the third transistor T3 may be electrically connected between the gate electrode of the first transistor T1 and the second electrode of the first transistor T1. The third transistor T3 may be turned on by the gate control signal GC of the gate control line GCL. Through the turned-on third transistor T3, the voltage difference between the second node N2 and the third node N3 may be initialized.

The fourth transistor T4 may be electrically connected between the gate initialization voltage line VGIL and the third node N3. That is, the fourth transistor T4 may be connected between the gate electrode of the first transistor T1 and the gate initialization voltage line VGIL. The fourth transistor T4 may be turned on by the scan initialization signal GI of the scan initialization line GIL. The potential of the third node N3 may be initialized through the turned-on fourth transistor T4.

The third transistor T3 and the fourth transistor T4 may be provided as N-type MOSFETs.

The seventh transistor T7 may be electrically connected between the fourth node N4 and the anode initialization voltage line VAIL. That is, the seventh transistor T7 may be electrically connected between the anode electrode of the light-emitting element LE and the anode initialization voltage line VAIL. The seventh transistor T7 may be turned on by the bias control signal GB of the bias control line GBL. The potential of the fourth node N4 may be initialized through the turned-on seventh transistor T7.

The eighth transistor T8 may be electrically connected between the first node N1 and the bias voltage line VBL. That is, the eighth transistor T8 may be electrically connected between the first electrode of the first transistor T1 and the bias voltage line VBL. The eighth transistor T8 may be turned on by the bias control signal GB of the bias control line GBL. The potential of the first node N1 may be initialized through the turned-on eighth transistor T8.

Among the first to eighth transistors T1, T2, T3, T4, T5, T6, T7, and T8, each of the transistors T1, T2, T5, T6, T7, and T8, excluding the third transistor T3 and the fourth transistor T4 may be implemented as a P-type MOSFET.

That is, while each of the third transistor T3 and the fourth transistor T4 among the first to eighth transistors T1, T2, T3, T4, T5, T6, T7, and T8 included in the light-emitting pixel driver EPD may be implemented as an N-type MOSFET, each of the remaining transistors T1, T2, T5, T6, T7, and T8 may be implemented as a P-type MOSFET.

Accordingly, according to embodiments, the circuit layer 120 may include a first semiconductor layer and a second semiconductor layer.

The first semiconductor layer may include a channel portion, a first electrode portion, and a second electrode portion of each of the first transistor T1, the second transistor T2, the fifth transistor T5, the sixth transistor T6, the seventh transistor T7, and the eighth transistor T8. In each of the first transistor T1, second transistor T2, fifth transistor T5, sixth transistor T6, seventh transistor T7, and eighth transistor T8, the channel portion may overlap the gate electrode. Further, in each of the first transistor T1, the second transistor T2, the fifth transistor T5, the sixth transistor T6, the seventh transistor T7, and the eighth transistor T8, the first electrode portion and the second electrode portion may be connected to both ends of the channel portion. The first electrode portion may become the first electrode, and the second electrode portion may become the second electrode.

The second semiconductor layer may include the channel portion, the first electrode portion, and the second electrode portion of each of the third transistor T3 and the fourth transistor T4. In each of the third transistor T3 and the fourth transistor T4, the channel portion may be located between the first gate electrode and the second gate electrode that overlap each other, and may overlap the first gate electrode and the second gate electrode. In each of the third transistor T3 and the fourth transistor T4, the first electrode portion and the second electrode portion may be connected to both ends of the channel portion. The first electrode portion may become the first electrode, and the second electrode portion may become the second electrode.

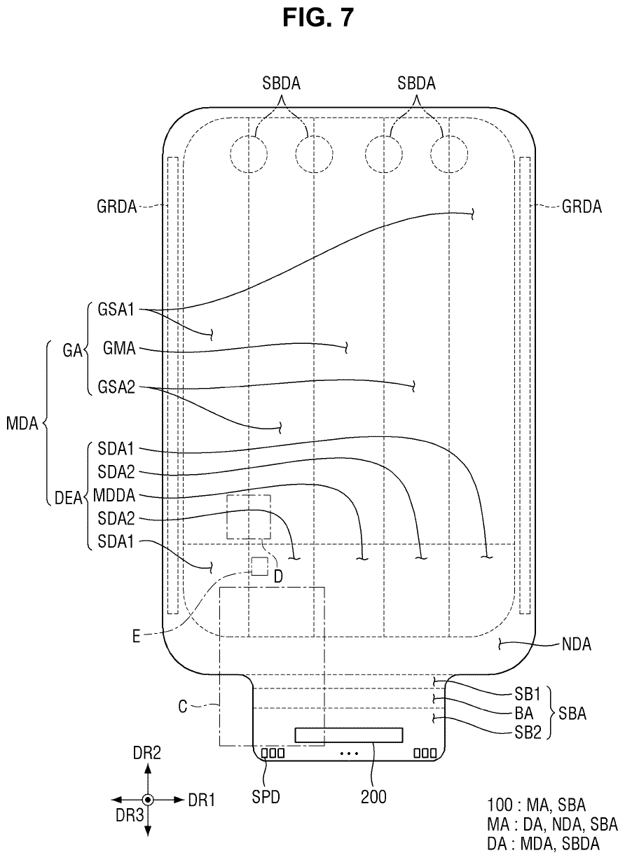

FIG. 7 is a plan view showing the substrate of FIG. 4.

Referring to FIG. 7, the substrate 110 of the display device 100 according to embodiments includes the main region MA corresponding to the display surface, and the sub-region SBA protruding from one side of the main region MA.

The main region MA may include the display area DA located at most of the center, and the non-display area NDA located at the periphery to surround the display area DA.

The display area DA may include a bypass area DEA located on one side adjacent to the sub-region SBA, and a general area GA located in the remaining area excluding the bypass area DEA.

The bypass area DEA may include a bypass middle area MDDA located at the center in the first direction DR1, a first bypass side area(s) SDA1 parallel to the bypass middle area MDDA in the first direction DR1 and in contact with the non-display area NDA, and a second bypass side area(s) SDA2 located between the bypass middle area MDDA and the first bypass side area SDA1.

The first bypass side area SDA1 may be located adjacent to the bent corner of the substrate 110 as compared to the bypass middle area MDDA and the second bypass side area SDA2.

The first bypass side area SDA1 and the second bypass side area SDA2 may be located between the bypass middle area MDDA and the non-display area NDA on both sides of the bypass middle area MDDA in the first direction DR1.

The general area GA may include a general middle area GMA connected to the bypass middle area MDDA of the bypass area DEA in the second direction DR2, a first general side area GSA1 connected to the first bypass side area SDA1 of the bypass area DEA in the second direction DR2, and a second general side area GSA2 connected to the second bypass side area SDA2 of the bypass area DEA in the second direction DR2.

The non-display area NDA may include a gate-driving circuit area GDRA where a gate driving circuit is located.

The gate-driving circuit area GDRA may be located in a portion of the non-display area NDA adjacent to at least one side of the display area DA in the first direction DR1.

The gate driving circuit of the gate-driving circuit area GDRA may sequentially transmit gate signals to gate lines. Here, the gate lines may include the scan write line GWL (see FIG. 6) that transmits the scan write signal GW (see FIG. 6), the scan initialization line GIL (see FIG. 6) that transmits the scan initialization signal GI (see FIG. 6), the gate control line GCL (see FIG. 6) that transmits the gate control signal GC (see FIG. 6), the bias control line GBL (see FIG. 6) that transmits the bias control signal GB (see FIG. 6), and the emission control line ECL (see FIG. 6) that transmits the emission control signal EC (see FIG. 6).

The sub-region SBA may include a bending region BA that is transformed into a bending shape, a first sub-region SB1 located between one side of the bending region BA and the main region MA, and a second sub-region SB2 connected to the other side of the bending region BA.

When the bending region BA is transformed into a bending shape, the second sub-region SB2 is located below the substrate 110, and overlaps the main region MA.

The display-driving circuit 200 may be located in the second sub-region SB2.

The signal pads SPD bonded to the display circuit board 300 may be located at one edge of the second sub-region SB2.

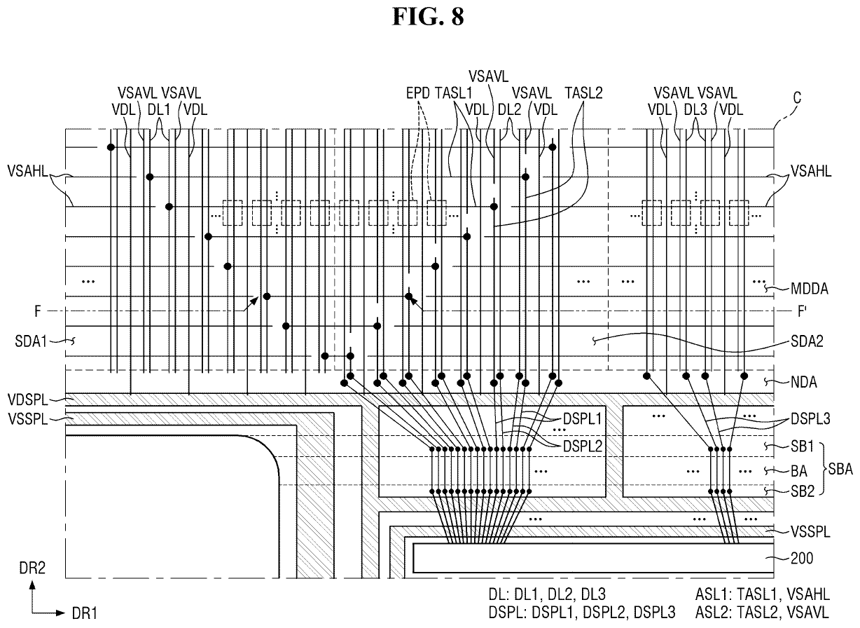

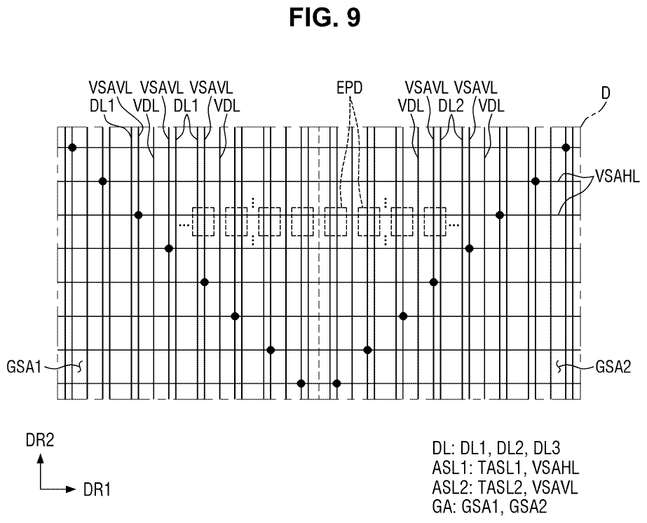

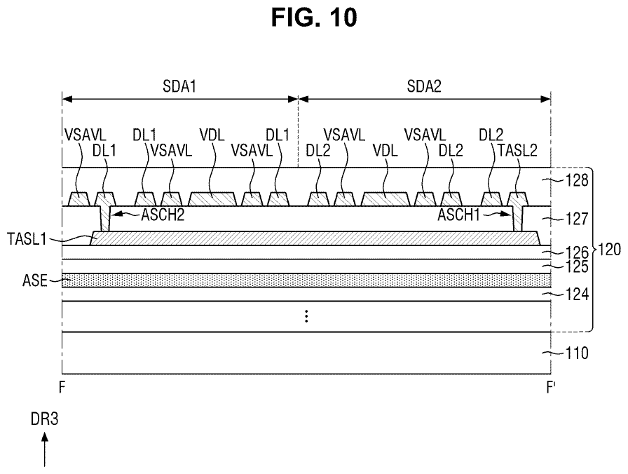

FIG. 8 is a layout diagram illustrating the circuit layer of part C of FIG. 7. FIG. 9 is a layout diagram illustrating the circuit layer of part D of FIG. 7. FIG. 10 is a cross-sectional view taken along the line F-F′ of FIG. 8.

Referring to FIGS. 8 and 9, the circuit layer 120 of the display device 100 according to embodiments may include the light-emitting pixel drivers EPD respectively electrically connected to the light-emitting elements LE of the element layer 130 and arranged side by side with each other in the first and second directions DR1 and DR2, data lines DL extending in the second direction DR2 for transmitting the data signal Vdata to the light-emitting pixel drivers EPD, a first bypass auxiliary line TASL1 extending in the first direction DR1 and electrically connected to a first data line DL1 adjacent to the non-display area NDA in the first direction DR1 among the data lines DL, and a second bypass auxiliary line TASL2 extending in the second direction DR2, paired with a second data line DL2 spaced further apart from the non-display area NDA than the first data line DL1 in the first direction DR1 among the data lines DL, and electrically connected to the first bypass auxiliary line TASL1.

The first bypass auxiliary line TASL1 located in the bypass area DEA may be a portion of first auxiliary lines ASL1 extending in the first direction DR1 and arranged in the second direction DR2. The first auxiliary lines ASL1 may further include second power auxiliary horizontal lines VSAHL to which the second power ELVSS is applied.

The second bypass auxiliary line TASL2 located in the second bypass side area SDA2 may be a portion of second auxiliary lines ASL2 extending in parallel with the data lines DL and respectively paired with the data lines DL. The second auxiliary lines ASL2 may further include second power auxiliary vertical lines VSAVL to which the second power ELVSS is applied.

According to embodiments, the circuit layer 120 may further include data supply lines DSPL located in the non-display area NDA and electrically connected to the display-driving circuit 200 and the data lines DL.

The data lines DL may include the first data line DL1 located in the first bypass side area SDA1 and the second data line DL2 located in the second bypass side area SDA2.

The first auxiliary lines ASL1 may include the first bypass auxiliary line TASL1 electrically connected to the first data line DL1 of the first bypass side area SDA1.

The second auxiliary lines ASL2 may include the second bypass auxiliary line TASL2 paired with the second data line DL2 of the second bypass side area SDA2 and electrically connected to the first bypass auxiliary line TASL1.

The data supply lines DSPL may include a first data supply line DSPL1 that transmits the data signal of the first data line DL1, and a second data supply line DSPL2 that transmits the data signal of the second data line DL2. According to embodiments, the data supply lines DSPL may extend to the second bypass side area SDA2 and the bypass middle area MDDA. Accordingly, the first data supply line DSPL1 may extend to the second bypass auxiliary line TASL2 of the second bypass side area SDA2, and may be electrically connected to the first data line DL1 through the second bypass auxiliary line TASL2 and the first bypass auxiliary line TASL1. On the other hand, the second data supply line DSPL2 may extend to the second bypass side area SDA2, and may be electrically connected to the second data line DL2 directly.

In this way, because the first data supply line DSPL1 extends not to the first data line DL1 of the first bypass side area SDA1, but to the second bypass auxiliary line TASL2 of the second bypass side area SDA2, the extension length of the first data supply line DSPL1 may be shortened. As a result, the width of the area required for the arrangement of the data supply lines DSPL may be reduced, so that the width of the non-display area NDA may be reduced.

In addition, because the data supply lines DSPL are not located in a portion of the non-display area NDA located between the bent corner of the substrate 110 and the first bypass side area SDA1, the width of the non-display area NDA can be further reduced.

The data lines DL may further include a third data line DL3 located in the bypass middle area MDDA. In addition, the data supply lines DSPL may further include a third data supply line DSPL3 that transmits the data signal of the third data line DL3. The third data supply line DSPL3 may extend to the bypass middle area MDDA, and may be electrically connected to the third data line DL3 directly.

The first bypass auxiliary line TASL1 extends from the second bypass auxiliary line TASL2 to the first data line DL1. The second bypass auxiliary line TASL2 extends from the first data supply line DSPL1 of the non-display area NDA to the first bypass auxiliary line TASL1. In this way, as the first bypass auxiliary line TASL1 and the second bypass auxiliary line TASL2 are limitedly arranged in the bypass area DEA, and the ends of the first bypass auxiliary line TASL1 and the ends of the second bypass auxiliary line TASL2 are arranged with regularity. Accordingly, visibility of the first bypass auxiliary line TASL1 and the second bypass auxiliary line TASL2 may be increased.

To reduce or prevent the likelihood of their visibility, the first auxiliary lines ASL1 may further include not only the first bypass auxiliary line TASL1 but also second power auxiliary horizontal lines VSAHL. Also, the second auxiliary lines ASL2 may further include not only the second bypass auxiliary lines TASL2 but also second power auxiliary vertical lines VSAVL. Two of the second power auxiliary horizontal lines VSAHL may extend from both ends of the first bypass auxiliary line TASL1 to the non-display area NDA. One of the second power auxiliary vertical lines VSAVL may extend from an area adjacent one end of the second bypass auxiliary line TASL2 to the non-display area NDA in a direction away from the sub-region SBA.

Accordingly, a part of each second data line DL2 is paired with the second bypass auxiliary line TASL2, and the other part of the second data line DL2 may be paired with the one second power auxiliary vertical line VSAVL extending from the one end of the second bypass auxiliary line TASL2.

Because the second bypass auxiliary line TASL2 is located only in the second bypass side area SDA2, the first data line DL1 of the first bypass side area SDA1 may be paired with the second power auxiliary vertical line VSAVL. The third data line DL3 of the bypass middle area MDDA may be paired with the second power auxiliary vertical line VSAVL.

As shown in FIG. 8, among the first auxiliary lines ASL1, the first bypass auxiliary line TASL1 may be located in the first bypass side area SDA1 and the second bypass side area SDA2 of the bypass area DEA, and the second power auxiliary horizontal lines VSAHL may be located in the bypass middle area MDDA of the bypass area DEA.

Also, as illustrated in FIG. 9, the second power auxiliary horizontal lines VSAHL and the second power auxiliary vertical lines VSAVL may be located in the general area GA.

As shown in FIG. 8, the circuit layer 120 may further include the first power supply line VDSPL and the second power supply line VSSPL that respectively transmit the first power ELVDD and the second power ELVSS for driving the light-emitting elements LE, respectively. The first power supply line VDSPL and the second power supply line VSSPL may be located in the non-display area NDA, and may extend to the sub-region SBA. The first power supply line VDSPL may be electrically connected to a first power pad for transmitting the first power ELVDD among the signal pads SPD located in the second sub-region SB2. The second power supply line VSSPL may be electrically connected to a second power pad for transmitting the second power ELVSS among the signal pads SPD located in the second sub-region SB2.

The second power auxiliary horizontal lines VSAHL may be electrically connected to the second power supply line VSSPL. The second power auxiliary vertical lines VSAVL may be electrically connected to the second power auxiliary horizontal lines VSAHL and the second power supply line VSSPL.

According to embodiments, the circuit layer 120 may further include the first power lines VDL electrically connected between the light-emitting pixel drivers EPD and the first power supply line VDSPL. The first power lines VDL may be located between two second auxiliary lines ASL2 adjacent to each other in the first direction DR1.

Referring to FIG. 10, the data lines DL, the second auxiliary lines ASL2, and the first power lines VDL may be located on an insulating layer (e.g., a first planarization layer 127) covering the first auxiliary lines ASL1.

For example, the first auxiliary lines ASL1 (e.g., first bypass auxiliary line TASL1) may be located in a first source-drain conductive layer on a second interlayer insulating layer 126.

The data lines DL, the second auxiliary lines ASL2, and the first power lines VDL may be located in the second source-drain conductive layer on the first planarization layer 127.

The second bypass auxiliary line TASL2 may be electrically connected to the first bypass auxiliary line TASL1 through a first auxiliary connection hole ASCH1 penetrating the first planarization layer 127. The first data line DL1 may be electrically connected to the first bypass auxiliary line TASL1 through a second auxiliary connection hole ASCH2 penetrating the first planarization layer 127.

According to embodiments, the first bypass auxiliary line TASL1 may overlap an auxiliary electrode portion ASE to which the gate initialization voltage VGINT is applied. In this way, a potential defect of distortion of a signal (e.g., the scan write signal GW, the scan initialization signal GI, the gate control signal GC, or the like) applied to the gate electrode of a transistor through a wire adjacent to the first bypass auxiliary line TASL1, which may otherwise occur due to coupling with the data signal Vdata of the first bypass auxiliary line TASL1, may be reduced.

Hereinafter, embodiments will be described taking the light-emitting pixel drivers EPD arranged in a portion of the second bypass side area SDA2 as an example. However, this is merely for simplicity of description, and may be similarly applicable to the first bypass side area SDA1, the bypass middle area MDDA, and the general area GA, except that the first data line DL1 or the third data line DL3 is located instead of the second data line DL2, that the second power auxiliary horizontal line VSAHL is located instead of the first bypass auxiliary line TASL1, and that the second power auxiliary vertical line VSAVL is located instead of the second bypass auxiliary line TASL2. Therefore, redundant description will be omitted below.

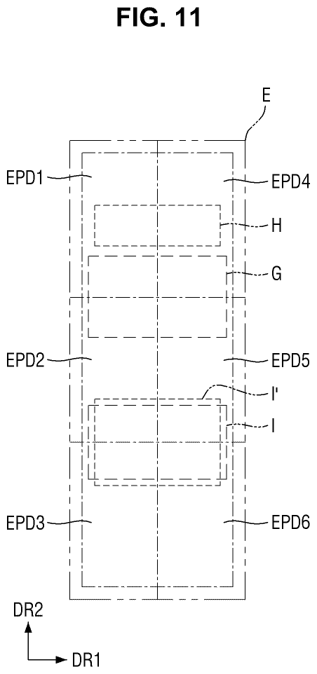

FIG. 11 is a layout diagram illustrating part E of FIG. 7.

Referring to FIG. 11, the light-emitting pixel drivers EPD of the circuit layer 120 of the display device 100 according to embodiments may include a first light-emitting pixel driver EPD1, a second light-emitting pixel driver EPD2, and a third light-emitting pixel driver EPD3 that are arranged side by side in the second direction DR2.

According to embodiments, the light-emitting pixel drivers EPD may further include a fourth light-emitting pixel driver EPD4 adjacent to the first light-emitting pixel driver EPD1 in the first direction DR1, a fifth light-emitting pixel driver EPD5 adjacent to the second light-emitting pixel driver EPD2 in the first direction DR1, and a sixth light-emitting pixel driver EPD6 adjacent to the third light-emitting pixel driver EPD3 in the first direction DR1.

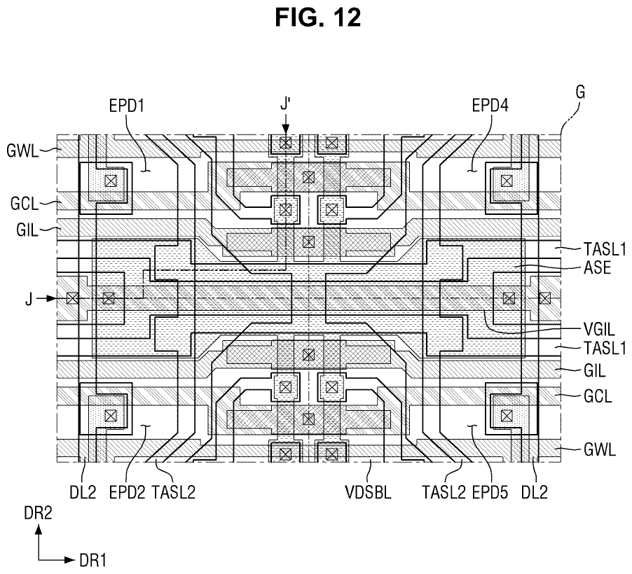

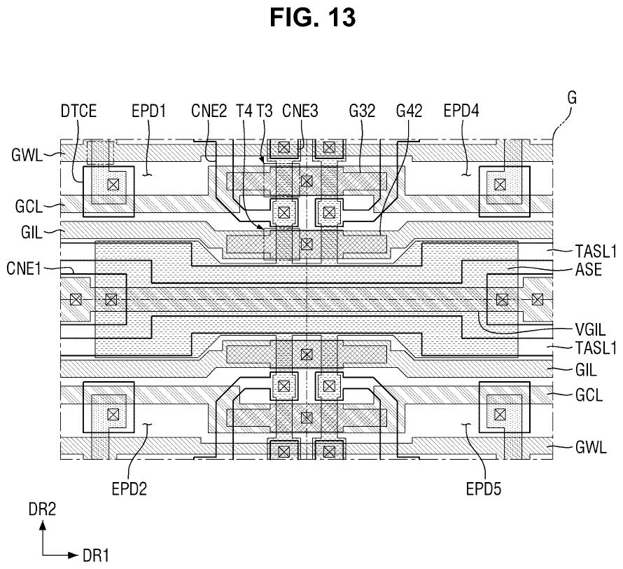

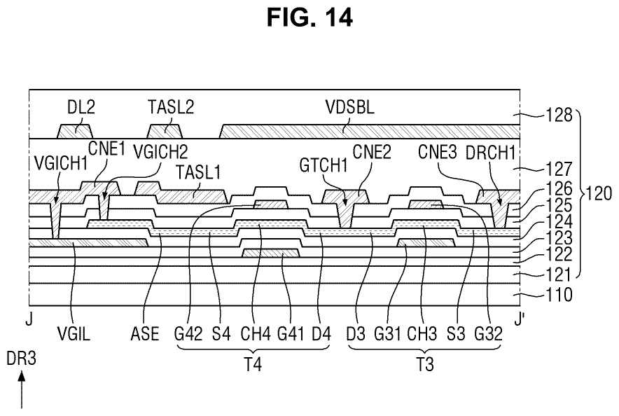

FIG. 12 is a plan view showing the circuit layer of part G of FIG. 11 according to one or more embodiments. FIG. 13 is a plan view showing the first source-drain conductive layer, the second semiconductor layer, the third gate conductive layer, the second gate conductive layer, and the first gate conductive layer of FIG. 12. FIG. 14 is a cross-sectional view taken along the line J-J′ of FIG. 12.

As shown in FIG. 12, the circuit layer 120 of the display device 100 according to embodiments may include the scan write line GWL, the gate control line GCL, the scan initialization line GIL, the gate initialization voltage line VGIL, and the first bypass auxiliary line TASL1 that extend in the first direction DR1, and the data line DL2 and the second bypass auxiliary line TASL2 that extend in the second direction DR2.

According to embodiments, the circuit layer 120 may further include a first power sub-line line VDSBL located adjacent to a boundary between the first light-emitting pixel driver EPD1 and the fourth light-emitting pixel driver EPD4, and to which the first power ELVDD is applied.

The first power sub-line line VDSBL may be located between the second bypass auxiliary lines TASL2.

As shown in FIG. 13, according to embodiments, the first light-emitting pixel driver EPD1 and the second light-emitting pixel driver EPD2 adjacent in the second direction DR2 may be electrically connected to one gate initialization voltage line VGIL located adjacent to a boundary between the first light-emitting pixel driver EPD1 and the second light-emitting pixel driver EPD2.

Each of the first light-emitting pixel driver EPD1 and the second light-emitting pixel driver EPD2 may include the auxiliary electrode portion ASE extending from a first electrode portion S4 (see FIG. 14) of the fourth transistor T4.

The auxiliary electrode portion ASE of the first light-emitting pixel driver EPD1, and the auxiliary electrode portion ASE of the second light-emitting pixel driver EPD2, may extend to the boundary between the first light-emitting pixel driver EPD1 and the second light-emitting pixel driver EPD2, and may be connected to each other. The auxiliary electrode portion ASE of the first light-emitting pixel driver EPD1 and the auxiliary electrode portion ASE of the second light-emitting pixel driver EPD2 may be electrically connected to the gate initialization voltage line VGIL through a first connection electrode CNE1.

According to embodiments, one or two first bypass auxiliary lines TASL1 may be located around the boundary between the first light-emitting pixel driver EPD1 and the second light-emitting pixel driver EPD2, and may be located adjacent to the gate initialization voltage line VGIL, while overlapping the auxiliary electrode portion ASE. In this way, as one or two first bypass auxiliary lines TASL1 located around the boundary between the first light-emitting pixel driver EPD1 and the second light-emitting pixel driver EPD2 are located adjacent to the gate initialization voltage line VGIL while overlapping the auxiliary electrode portion ASE to which the gate initialization voltage VGINT is applied, coupling defects caused by the data signal Vdata of the first bypass auxiliary line TASL1 may be reduced. That is, the signals of the wires (e.g., the scan write line GWL, the gate control line GCL, the scan initialization line GIL, and the like) adjacent to the first bypass auxiliary line TASL1, extending in the first direction DR1 in parallel with the first bypass auxiliary line TASL1, and electrically connected to the gate electrode of the transistor, may be less affected by the data signal Vdata of the first bypass auxiliary line TASL1.

Accordingly, because malfunctions of the transistors T1, T2, T3, T4, T5, T6, T7, and T8 included in the light-emitting pixel driver EPD may be reduced, defects, such as stains and spots may be reduced, thereby improving the display quality of the display device 100.

According to one or more embodiments, one of two first bypass auxiliary lines TASL1 located adjacent to the boundary between the first light-emitting pixel driver EPD1 and the second light-emitting pixel driver EPD2 may be located adjacent to one side in the second direction DR2 of one gate initialization voltage line VGIL located adjacent to the boundary between the first light-emitting pixel driver EPD1 and the second light-emitting pixel driver EPD2. In addition, the other of the two first bypass auxiliary lines TASL1 located adjacent to the boundary between the first light-emitting pixel driver EPD1 and the second light-emitting pixel driver EPD2 may be located adjacent to the other side in the second direction DR2 of the one gate initialization voltage line VGIL.

That is, the one gate initialization voltage line VGIL located adjacent to the boundary between the first light-emitting pixel driver EPD1 and the second light-emitting pixel driver EPD2 may be located between the two first bypass auxiliary lines TASL1 located adjacent to the boundary between the first light-emitting pixel driver EPD1 and the second light-emitting pixel driver EPD2. In other words, the two first bypass auxiliary lines TASL1 located adjacent to the boundary between the first light-emitting pixel driver EPD1 and the second light-emitting pixel driver EPD2 may overlap the first light-emitting pixel driver EPD1 and the second light-emitting pixel driver EPD2, respectively.

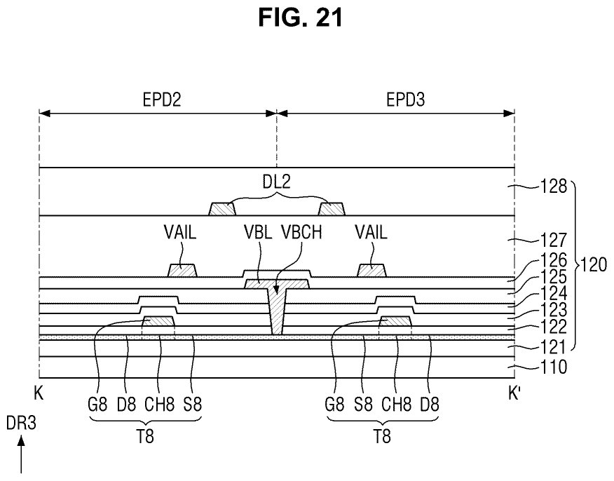

As shown in FIG. 14, the circuit layer 120 of the display device 100 according to embodiments may include a first semiconductor layer CH8, S8, and D8 (see FIG. 21) located on the substrate 110, a first gate-insulating layer 122 covering the first semiconductor layer, a first gate conductive layer G41 and G8 (see FIG. 21) located on the first gate-insulating layer 122, a second gate-insulating layer 123 covering the first gate conductive layer, a second gate conductive layer G31 and VGIL located on the second gate-insulating layer 123, a first interlayer insulating layer 124 covering the second gate conductive layer, a second semiconductor layer CH3, S3, D3, CH4, S4, and D4 located on the first interlayer insulating layer 124, a third gate-insulating layer 125 covering the second semiconductor layer, a third gate conductive layer G32, G42, and VBL (see FIG. 21) located on the third gate-insulating layer 125, the second interlayer insulating layer 126 covering the third gate conductive layer, a first source-drain conductive layer TASL1, CNE1, CNE2, CNE3, and VAIL (see FIG. 21) located on the second interlayer insulating layer 126, a first planarization layer 127 covering the first source-drain conductive layer, a second source-drain conductive layer DL2, VDSBL, and TASL2 located on the first planarization layer 127, and a second planarization layer 128 covering the second source-drain conductive layer.

According to embodiments, the circuit layer 120 may further include a buffer layer 121 covering the substrate 110. In this case, the first semiconductor layer may be located on the buffer layer 121.

As shown in FIGS. 13 and 14, in each of the light-emitting pixel drivers EPD, a channel portion CH3 of the third transistor T3 may be located in a region where the gate control line GCL and the second semiconductor layer on the first interlayer insulating layer 124 intersect.

In each of the light-emitting pixel drivers EPD, a channel portion CH4 of the fourth transistor T4 may be located in a region where the scan initialization line GIL and the second semiconductor layer on the first interlayer insulating layer 124 intersect.

The third transistor T3 may include the channel portion CH3, a first electrode portion S3, and a second electrode portion D3 provided as the second semiconductor layer on the first interlayer insulating layer 124, a first gate electrode G31 that is a portion of the gate control line GCL provided as the second gate conductive layer on the second gate-insulating layer 123, and a second gate electrode G32 provided as the third gate conductive layer on the third gate-insulating layer 125.

The fourth transistor T4 may include the channel portion CH4, the first electrode portion S4, and a second electrode portion D4 provided as the second semiconductor layer on the first interlayer insulating layer 124, a first gate electrode G41 that is a portion of the scan initialization line GIL provided as the first gate conductive layer on the first gate-insulating layer 122, and a second gate electrode G42 provided as the third gate conductive layer on the third gate-insulating layer 125.

That is, the second semiconductor layer on the first interlayer insulating layer 124 may include the channel portions CH3 and CH4, the first electrode portions S3 and S4, and the second electrode portions D3 and D4 of the third and fourth transistors T3 and T4.

In addition, the first electrode portion S4 of the fourth transistor T4 may be connected to the auxiliary electrode portion ASE. That is, the second semiconductor layer on the first interlayer insulating layer 124 may further include the auxiliary electrode portion ASE. The auxiliary electrode portion ASE may extend in the first direction DR1, and may overlap the gate initialization voltage line VGIL and the first bypass auxiliary line TASL1.

As shown in FIG. 13, the auxiliary electrode portion ASE of the first light-emitting pixel driver EPD1, and the auxiliary electrode portion ASE of the second light-emitting pixel driver EPD2, may be connected to each other, and may be electrically connected to the gate initialization voltage line VGIL through the first connection electrode CNE1.

As shown in FIG. 14, the second gate conductive layer on the second gate-insulating layer 123 may include the gate initialization voltage line VGIL.

The first source-drain conductive layer on the second interlayer insulating layer 126 may include the first bypass auxiliary line TASL1, the first connection electrode CNE1, a second connection electrode CNE2, and a third connection electrode CNE3. When the first bypass auxiliary line TASL1 is a portion of the first auxiliary lines ASL1, the first source-drain conductive layer on the second interlayer insulating layer 126 may further include the first auxiliary lines ASL1.

As shown in FIG. 13, according to embodiments, the first electrode portion S4 of the fourth transistor T4 of the second light-emitting pixel driver EPD2, and the first electrode portion S4 of the fourth transistor T4 of the first light-emitting pixel driver EPD1, may be connected to each other, and may be electrically connected to one gate initialization voltage line VGIL.

In one example, the gate initialization voltage line VGIL may be electrically connected to the first electrode portion S4 of the fourth transistor T4 through the first connection electrode CNE1.

The first connection electrode CNE1 may be electrically connected to the gate initialization voltage line VGIL through a first gate initialization connection hole VGICH1, and electrically connected to the first electrode portion S4 of the fourth transistor T4 through a second gate initialization connection hole VGICH2.

The second electrode portion D3 of the third transistor T3 and the second electrode portion D4 of the fourth transistor T4 may be connected to each other, and may be electrically connected to the gate electrode of the first transistor T1 through the second connection electrode CNE2. That is, the second connection electrode CNE2 may correspond to the third node N3 (see FIG. 6). The second connection electrode CNE2 may be electrically connected to the second electrode portion D4 of the fourth transistor T4 through a first gate connection hole GTCH1.

The first electrode portion S3 of the third transistor T3 may be electrically connected to the second electrode of the first transistor T1 through the third connection electrode CNE3. That is, the third connection electrode CNE3 may correspond to the second node N2 (see FIG. 6). The third connection electrode CNE3 may be electrically connected to the second electrode portion D4 of the fourth transistor T4 through a first drain connection hole DRCH1.

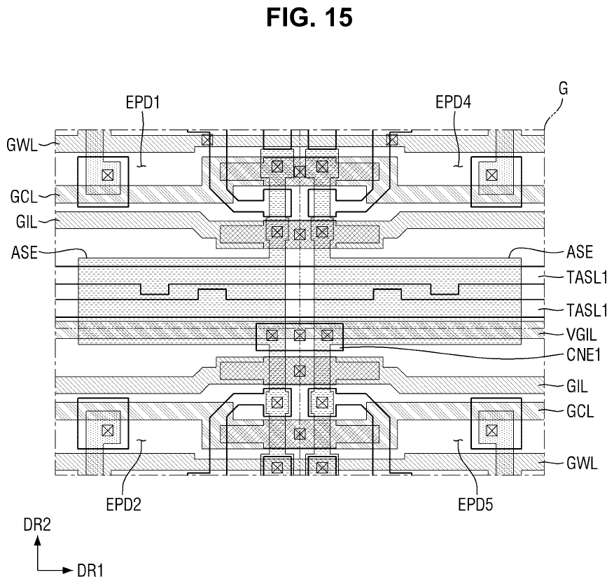

FIG. 15 is a plan view showing the first source-drain conductive layer, the second semiconductor layer, the third gate conductive layer, the second gate conductive layer, and the first gate conductive layer in the circuit layer of part G of FIG. 11 according to one or more embodiments.

The display device 100 according to one or more embodiments shown in FIG. 15 is substantially the same as that of the embodiments shown in FIGS. 1 to 14, except that two first bypass auxiliary lines TASL1 located adjacent to the boundary between the first light-emitting pixel driver EPD1 and the second light-emitting pixel driver EPD2 are arranged side by side on one side in the second direction DR2 of one gate initialization voltage line VGIL that is adjacent to the boundary between the first light-emitting pixel driver EPD1 and the second light-emitting pixel driver EPD2. Therefore, redundant description will be omitted below.

That is, according to one or more embodiments of FIG. 15, two first bypass auxiliary lines TASL1 located adjacent to the boundary between the first light-emitting pixel driver EPD1 and the second light-emitting pixel driver EPD2 may overlap the first light-emitting pixel driver EPD1 facing one side in the second direction DR2 of one gate initialization voltage line VGIL, between the first and second light-emitting pixel drivers EPD1 and EPD2.

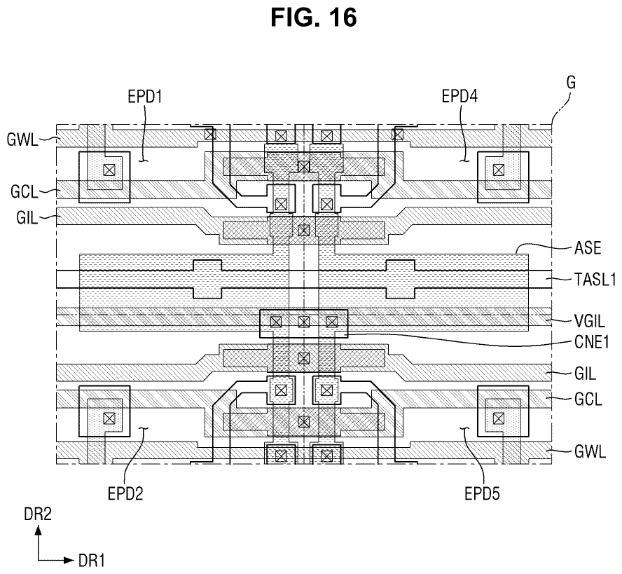

FIG. 16 is a plan view showing the first source-drain conductive layer, the second semiconductor layer, the third gate conductive layer, the second gate conductive layer, and the first gate conductive layer in the circuit layer of part G of FIG. 11 according to one or more embodiments.

The display device 100 according to one or more embodiments shown in FIG. 16 is substantially the same as that of one or more embodiments of FIG. 15, except that one first bypass auxiliary line TASL1 is located at the boundary between the first light-emitting pixel driver EPD1 and the second light-emitting pixel driver EPD2. Therefore, redundant description will be omitted below. That is, according to one or more embodiments of FIG. 16, two light-emitting pixel drivers EPD adjacent in the second direction DR2 and one first bypass auxiliary line TASL1 may be arranged alternately in the second direction DR2.

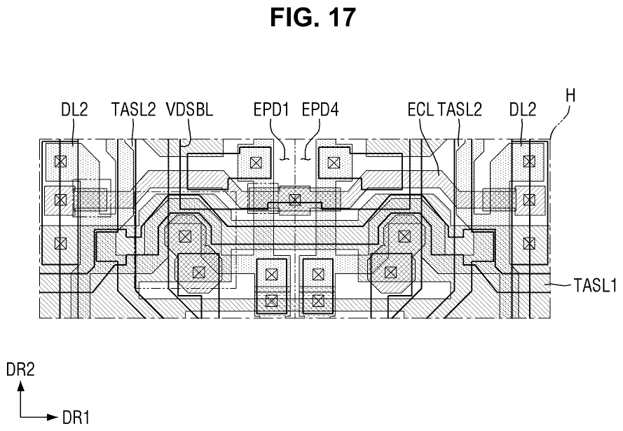

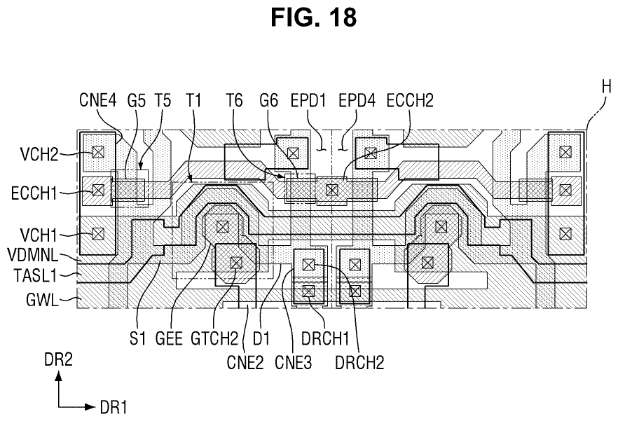

FIG. 17 is a plan view showing the circuit layer of part H of FIG. 11 according to one or more embodiments. FIG. 18 is a plan view showing the first source-drain conductive layer, the second semiconductor layer, the third gate conductive layer, the second gate conductive layer, and the first gate conductive layer of FIG. 17.

As shown in FIGS. 17 and 18, the first power line VDL of the circuit layer 120 of the display device 100 according to embodiments may include a first power main line VDMNL extending in the first direction DR1 and a first power sub-line VDSBL extending in the second direction DR2.

The first power sub-line VDSBL may be located in the same layer as the data line DL2 and the second bypass auxiliary line TASL2. That is, the first power sub-line VDSBL may be located in the second source-drain conductive layer on the first planarization layer 127. The first power sub-line VDSBL may extend in the second direction DR2 in parallel with the data line DL2 and the second bypass auxiliary line TASL2. The first power sub-line VDSBL may be located between one second bypass auxiliary line TASL2 overlapping the first light-emitting pixel driver EPD1 and another second bypass auxiliary line TASL2 overlapping the fourth light-emitting pixel driver EPD4 adjacent to the first light-emitting pixel driver EPD1 in the first direction DR1.

As shown in FIG. 18, the first power main line VDMNL may overlap the gate electrode of the first transistor T1, and may extend in the first direction DR1. In this way, the first pixel capacitor PC1 may be provided by the region where the gate electrode of the first transistor T1 and the first power main line VDMNL overlap each other.

For example, the gate electrode of the first transistor T1 may be located in the first gate conductive layer on the first gate-insulating layer 122 so as to be adjacent to the channel portion of the first transistor T1 located in the first semiconductor layer.

In addition, the scan write line GWL may be located in the first gate conductive layer on the first gate-insulating layer 122.

The first power main line VDMNL may be located in the second gate conductive layer on the second gate-insulating layer 123.

As shown in FIG. 18, according to one or more embodiments, the first bypass auxiliary line TASL1 may overlap the first power main line VDMNL. In this way, the first bypass auxiliary line TASL1 may be spaced apart from the boundary between the first light-emitting pixel driver EPD1 and the second light-emitting pixel driver EPD2. Accordingly, because the first bypass auxiliary line TASL1 may be spaced apart from the scan initialization line GIL and the gate control line GCL, the effect of the data signal Vdata of the first bypass auxiliary line TASL1 on the scan initialization signal GI of the scan initialization line GIL and on the gate control signal GC of the gate control line GCL may be reduced.

In addition, the effect of the data signal Vdata of the first bypass auxiliary line TASL1 on the scan write signal GW of the scan write line GWL may be shielded by the first power ELVDD applied to the first power main line VDMNL overlapping the first bypass auxiliary line TASL1.

In addition, because the first bypass auxiliary line TASL1 is not located adjacent to the boundary between the first light-emitting pixel driver EPD1 and the second light-emitting pixel driver EPD2, the width of the area separately allocated for the arrangement of the first bypass auxiliary line TASL1 may be reduced.

As shown in FIG. 18, in each of the light-emitting pixel drivers EPD, a channel portion CH5 of the fifth transistor T5 and a channel portion CH6 of the sixth transistor T6 may each be located in a region where the emission control line ECL and the first semiconductor layer on the substrate 110 intersect.

A gate electrode G5 of the fifth transistor T5 and a gate electrode G6 of the sixth transistor T6 may be located between the first semiconductor layer and the emission control line ECL, while overlapping the emission control line ECL. For example, the gate electrode G5 of the fifth transistor T5 and the gate electrode G6 of the sixth transistor T6 may be located in the first gate conductive layer on the first gate-insulating layer 122.

The emission control line ECL may be located in the third gate conductive layer on the third gate-insulating layer 125. The gate electrode G5 of the fifth transistor T5 may be electrically connected to the emission control line ECL through a first emission control connection hole ECCH1. The gate electrode G6 of the sixth transistor T6 may be electrically connected to the emission control line ECL through a second emission control connection hole ECCH2.

The gate electrode G6 of the sixth transistor T6 of the first light-emitting pixel driver EPD1 and the gate electrode G6 of the sixth transistor T6 of the fourth light-emitting pixel driver EPD4 may be connected to each other.

The first electrode portion of the fifth transistor T5 may be electrically connected to the first power main line VDMNL through a fourth connection electrode CNE4. The fourth connection electrode CNE4 may be electrically connected to the first power main line VDMNL through a first power connection hole VCH1, and electrically connected to the first electrode portion of the fifth transistor T5 through a second power connection hole VCH2.

The third connection electrode CNE3 may be electrically connected to the second electrode portion D4 of the fourth transistor T4 through the first drain connection hole DRCH1, and may be electrically connected to the second electrode portion D1 of the first transistor T1 through a second drain connection hole DRCH2.

The second connection electrode CNE2 may be electrically connected to a gate connection electrode GEE through a second gate connection hole GTCH2. The gate connection electrode GEE may be electrically connected to the gate electrode of the first transistor T1. Accordingly, the gate electrode of the first transistor T1 may be electrically connected to the second electrode portion D4 of the fourth transistor T4 through the gate connection electrode GEE and the second connection electrode CNE2.

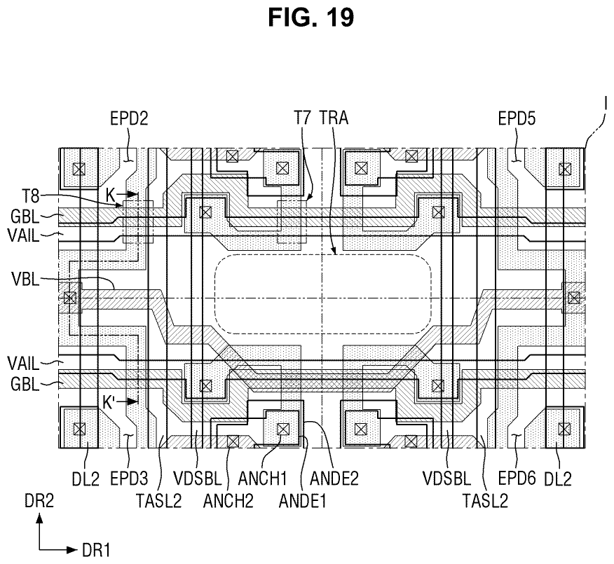

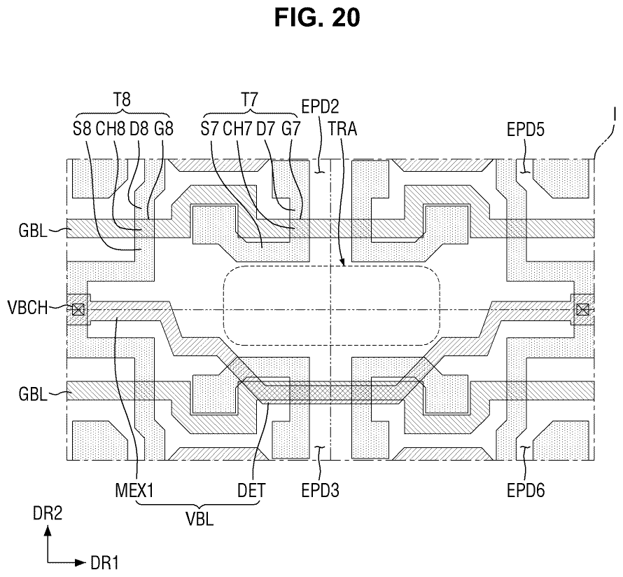

FIG. 19 is a plan view showing the circuit layer of part I of FIG. 11 according to one or more embodiments. FIG. 20 is a plan view showing the first semiconductor layer, the first gate conductive layer, and the bias voltage line of FIG. 19. FIG. 21 is a cross-sectional view taken along the line K-K′ of FIG. 19.

As shown in FIG. 6, the circuit layer 120 includes the bias voltage line VBL for transmitting the bias voltage VBS to the light-emitting pixel drivers EPD.

As shown in FIGS. 19, 20, and 21, according to embodiments, the second light-emitting pixel driver EPD2 and the third light-emitting pixel driver EPD3 adjacent to each other in the second direction DR2 may be electrically connected to one bias voltage line VBL located adjacent to a boundary between the second light-emitting pixel driver EPD2 and the third light-emitting pixel driver EPD3.

One bias voltage line VBL may extend in the first direction DR1, and may be located adjacent to a boundary between the fifth light-emitting pixel driver EPD5 and the sixth light-emitting pixel driver EPD6 respectively adjacent to the second light-emitting pixel driver EPD2 and the third light-emitting pixel driver EPD3 in the first direction DR1. The fifth light-emitting pixel driver EPD5 and the sixth light-emitting pixel driver EPD6 may be electrically connected to one bias voltage line VBL. That is, the second, third, fifth, and sixth light-emitting pixel drivers EPD2, EPD3, EPD5, and EPD6 adjacent to each other in the first and second directions DR1 and DR2 may share one bias voltage line VBL.

In this way, compared to a structure in which two light-emitting pixel drivers EPD2 and EPD3 or EPD5 and EPD6 adjacent in the second direction DR2 are connected to two bias voltage lines VBL, the number of the bias voltage lines VBL arranged in the main region MA may be reduced by half. That is, a space may be provided between two light-emitting pixel drivers EPD2 and EPD3 or EPD5 and EPD6, which are adjacent in the second direction DR2. Accordingly, a portion of the display area DA, including the contact points between the second, third, fifth, and sixth light-emitting pixel drivers EPD2, EPD3, EPD5, and EPD6 adjacent to each other in the first and second directions DR1 and DR2, may be provided as a light-transmitting area TRA in which no conductive layers are located.

Because an optical path passing through the display device 100 may be provided by the light-transmitting area TRA, even if the optical devices 18 located below the display device 100 overlap the display area DA, the functions of the optical devices 18 may be executed through the light-transmitting area TRA. Therefore, the resolution of the sub-display area SBDA overlapping the optical devices 18 in the display area DA may be maintained at the same level as the resolution of the main display area MDA, thereby reducing or preventing degradation of the display quality caused by the arrangement of the optical devices 18.

As shown in FIG. 19, according to embodiments, the anode initialization voltage line VAIL extends in the first direction DR1, one anode initialization voltage line VAIL may overlap the second light-emitting pixel driver EPD2 and the fifth light-emitting pixel driver EPD5 adjacent each other in the first direction DR1, and another anode initialization voltage line VAIL may overlap the third light-emitting pixel driver EPD3 and the sixth light-emitting pixel driver EPD6 adjacent each other in the first direction DR1.

The bias control line GBL may also extend in the first direction DR1, one bias control line GBL may overlap the second light-emitting pixel driver EPD2 and the fifth light-emitting pixel driver EPD5 adjacent in the first direction DR1, and another bias control line GBL may overlap the third light-emitting pixel driver EPD3 and the sixth light-emitting pixel driver EPD6 adjacent in the first direction DR1.

The anode initialization voltage line VAIL and the bias control line GBL may be located adjacent to the bias voltage line VBL in the second direction DR2.

In each of the light-emitting pixel drivers EPD, a channel portion CH7 of the seventh transistor T7 and a channel portion CH8 of the eighth transistor T8 may be located in regions where the bias control line GBL and the first semiconductor layer intersect.

The seventh transistor T7 may be electrically connected to the anode initialization voltage line VAIL through an anode initialization voltage connection hole.

The eighth transistor T8 may be electrically connected to the bias voltage line VBL through a bias voltage connection hole VBCH.

The data line DL and the first power line VDL may extend in the second direction DR2.

As shown in FIG. 21, the circuit layer 120 of the display device 100 according to embodiments may include the first semiconductor layer CH8, S8, and D8 located on the substrate 110, the first gate-insulating layer 122 covering the first semiconductor layer, the first gate conductive layer G8 (G41 in FIG. 14) located on the first gate-insulating layer 122, the second gate-insulating layer 123 covering the first gate conductive layer, the second gate conductive layer (G31 and VGIL in FIG. 14) located on the second gate-insulating layer 123, the first interlayer insulating layer 124 covering the second gate conductive layer, the second semiconductor layer (CH3, S3, D3, CH4, S4, and D4 in FIG. 14) located on the first interlayer insulating layer 124, the third gate-insulating layer 125 covering the second semiconductor layer, the third gate conductive layer VBL (G32 and G42 in FIG. 14) located on the third gate-insulating layer 125, the second interlayer insulating layer 126 covering the third gate conductive layer, the first source-drain conductive layer VAIL (CNE1, CNE2, and CNE3 in FIG. 14) located on the second interlayer insulating layer 126, the second source-drain conductive layer DL (VDL in FIG. 14) located on the first planarization layer 127, and the second planarization layer 128 covering the second source-drain conductive layer.

As shown in FIGS. 20 and 21, the seventh transistor T7 may include the channel portion CH7, the first electrode portion S7, and the second electrode portion D7 that are provided as the first semiconductor layer, and the gate electrode G7 provided as a part of the bias control line GBL that overlaps the channel portion CH7.

The eighth transistor T8 may include the channel portion CH8, the first electrode portion S8, and the second electrode portion D8 that are provided as the first semiconductor layer, and the gate electrode G8 provided as another part of the bias control line GBL that overlaps the channel portion CH8.

In accordance with embodiments, the first electrode portion S8 of the eighth transistor T8 of the second light-emitting pixel driver EPD2 and the first electrode portion S8 of the eighth transistor T8 of the third light-emitting pixel driver EPD3 may be connected to each other, and may be electrically connected to one bias voltage line VBL through the bias voltage connection hole VBCH (see FIG. 19).

As shown in FIG. 21, the first semiconductor layer on the buffer layer 121 may include the channel portion CH8, the first electrode portion S8, and the second electrode portion D8 of the eighth transistor T8.

Referring to FIG. 20, the first semiconductor layer on the buffer layer 121 may further include the channel portion CH7, the first electrode portion S7, and the second electrode portion D7 of the seventh transistor T7.

Referring to FIG. 6, the first transistor T1, the second transistor T2, the fifth transistor T5, and the sixth transistor T6 are provided as P-type MOSFETs similarly to the seventh transistor T7 and the eighth transistor T8, so that the first semiconductor layer on the buffer layer 121 may further include the channel portion, the first electrode portion, and the second electrode portion of each of the first transistor T1, the second transistor T2, the fifth transistor T5, and the sixth transistor T6.

The first gate conductive layer on the first gate-insulating layer 122 may include the gate electrode G8 of the eighth transistor T8.

Referring to FIG. 20, the gate electrode G7 of the seventh transistor T7 and the gate electrode G8 of the eighth transistor T8 are parts of the bias control line GBL, so that the first gate conductive layer on the first gate-insulating layer 122 may include the bias control line GBL.

The third gate conductive layer on the third gate-insulating layer 125 may include the bias voltage line VBL. The first source-drain conductive layer on the second interlayer insulating layer 126 may include the anode initialization voltage line VAIL. The second source-drain conductive layer on the first planarization layer 127 may include the data line DL2.

As shown in FIG. 20, according to embodiments, one bias voltage line VBL may include a first main extension portion MEX1 extending in the first direction DR1, and a bypass portion DET connected to the first main extension portion MEX1 and bypassing the light-transmitting area TRA. The first main extension portion MEX1 may be located adjacent to the boundary between two light-emitting pixel drivers EPD2 and EPD3 or EPD5 and EPD6 respectively adjacent each other in the second direction DR2. The bias voltage connection hole VBCH may overlap the first main extension portion MEX1.

The light-transmitting area TRA may be a partial area of the display area DA that includes the contact points between the second, third, fifth, and sixth light-emitting pixel drivers EPD2, EPD3, EPD5, and EPD6 adjacent to each other in the first direction DR1 and the second direction DR2.

The bypass portion DET may resemble a U-shape that is convex on one side in the second direction DR2 compared to the first main extension portion MEX1. In this way, according to embodiments, the bias voltage line VBL further includes the bypass portion DET as well as the first main extension portion MEX1, so that a wider light-transmitting area TRA may be provided.

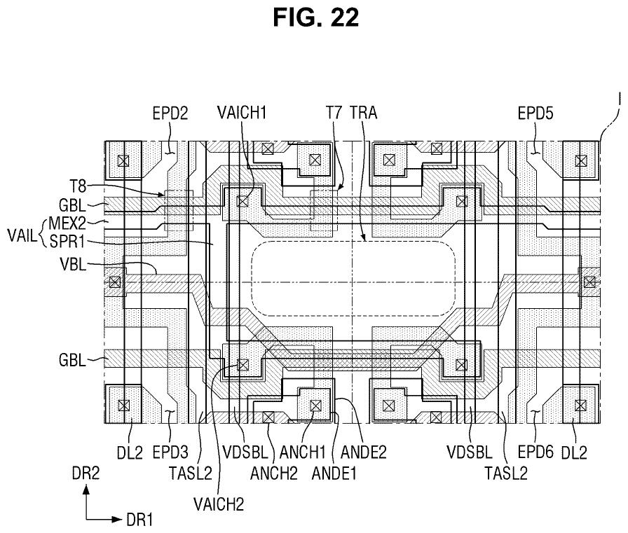

FIG. 22 is a plan view showing part I of FIG. 11 according to one or more embodiments.

The display device 100 of one or more embodiments shown in FIG. 22 is substantially the same as the embodiments shown in FIGS. 1 to 21, except that the second light-emitting pixel driver EPD2 and the third light-emitting pixel driver EPD3 adjacent to each other in the second direction DR2 may share one anode initialization voltage line VAIL, so that redundant description will be omitted in the following description.

In accordance with one or more embodiments of FIG. 22, the anode initialization voltage line VAIL may include a second main extension portion MEX2 located adjacent to the first main extension portion MEX1 of the bias voltage line VBL, and extending in the first direction DR1, and also may include a first sub-protruding portion SPR1 protruding from the second main extension portion MEX2 and extending in the second direction DR2.

The second main extension portion MEX2 may overlap the second light-emitting pixel driver EPD2.

The first sub-protruding portion SPR1 may intersect the bias voltage line VBL. One end of the first sub-protruding portion SPR1 may overlap the third light-emitting pixel driver EPD3.

Accordingly, the first electrode portion S7 of the seventh transistor T7 of the second light-emitting pixel driver EPD2 may be electrically connected to the anode initialization voltage line VAIL through a first anode initialization connection hole VAICH1 overlapping the second main extension portion MEX2. Further, the first electrode portion S7 of the seventh transistor T7 of the third light-emitting pixel driver EPD3 may be electrically connected to the anode initialization voltage line VAIL through a second anode initialization connection hole VAICH2 overlapping the first sub-protruding portion SPR1.

In addition, because the second main extension portion MEX2 extends in the first direction DR1, the fifth light-emitting pixel driver EPD5 adjacent to the second light-emitting pixel driver EPD2 in the first direction DR1 may be electrically connected to the anode initialization voltage line VAIL through the first anode initialization connection hole VAICH1, and the sixth light-emitting pixel driver EPD6 adjacent to the third light-emitting pixel driver EPD3 in the first direction DR1 may be electrically connected to the anode initialization voltage line VAIL through the second anode initialization connection hole VAICH2.

Accordingly, in accordance with one or more embodiments, the second, third, fifth, and sixth light-emitting pixel drivers EPD2, EPD3, EPD5, and EPD6 adjacent to each other in the first direction DR1 and the second direction DR2 share one anode initialization voltage line VAIL, so that the number of anode initialization voltage lines VAIL arranged in the main region MA may be reduced by half. Therefore, even if the number of light-emitting pixel drivers EPD is not changed, the light-transmitting area TRA including the contact points between the second, third, fifth, and sixth light-emitting pixel drivers EPD2, EPD3, EPD5 and EPD6 may secure a wider area by the reduction in the number of anode initialization voltage lines VAIL.

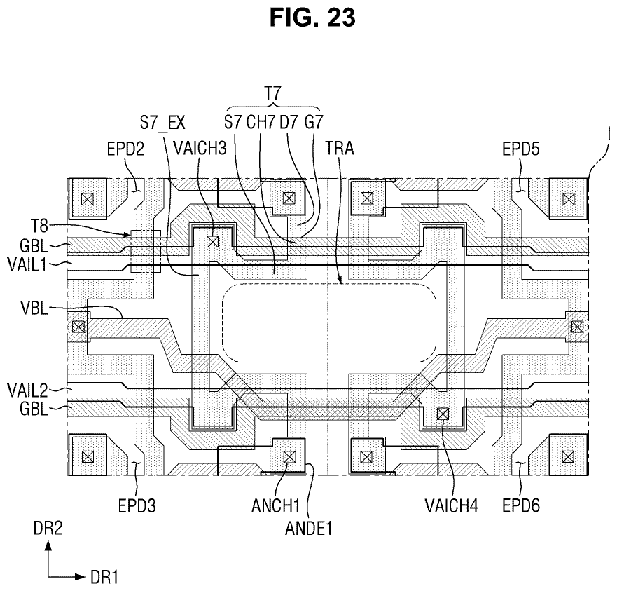

FIG. 23 is a plan view showing part I of FIG. 11 according to one or more embodiments.

The display device 100 of one or more embodiments shown in FIG. 23 is substantially the same as the embodiments shown in FIGS. 1 to 21 except that the circuit layer 120 includes, instead of the anode initialization voltage line VAIL, a first anode initialization voltage line VAIL1 and a second anode initialization voltage line VAIL2 arranged alternately in the second direction DR2, so that redundant description will be omitted in the following description.

As shown in FIG. 5, the emission areas EA may include the first emission area EA1, the second emission area EA2, and the third emission area EA3. The first emission area EA1, the second emission area EA2, and the third emission area EA3 may be arranged side by side in the second direction DR2. The first emission area EA1 and the third emission area EA3 may be arranged alternately in the first direction DR1.

The second emission areas EA2 may be arranged side by side in the first direction DR1. The second emission area EA2 may be adjacent to the first emission area EA1 and the third emission area EA3 in a fourth direction DR4 or a fifth direction DR5 oblique to the first direction DR1 and the second direction DR2. Because the second emission area EA2 has a smaller width than the first emission area EA1 and the third emission area EA3, in one or more embodiments, when the light-emitting element of the second emission area EA2 is initialized to the same voltage level as the light-emitting elements of the first emission area EA1 and the third emission area EA3, it may be difficult to display luminance corresponding to the data signal Vdata.

Accordingly, in accordance with one or more embodiments of FIG. 23, the circuit layer 120 may include the first anode initialization voltage line VAIL1 for transmitting a first anode initialization voltage for initializing the light-emitting elements of the first emission area EA1 and the third emission area EA3, and the second anode initialization voltage line VAIL2 for transmitting a second anode initialization voltage for initializing the light-emitting element of the second emission area EA2.

The voltage level of the second anode initialization voltage may be different from the voltage level of the first anode initialization voltage. For example, each of the second light-emitting pixel driver EPD2 and the third light-emitting pixel driver EPD3 may be electrically connected to the light-emitting element LE of one of the first emission area EA1 and the third emission area EA3.

Each of the fifth light-emitting pixel driver EPD5 and the sixth light-emitting pixel driver EPD6 may be electrically connected to the light-emitting element LE of the second emission area EA2.

In accordance with one or more embodiments of FIG. 23, the first anode initialization voltage line VAIL1 may extend in the first direction DR1, and may be located adjacent to one side of the bias voltage line VBL in the second direction DR2. The second anode initialization voltage line VAIL2 may extend in the first direction DR1, and may be located adjacent to the other side of the bias voltage line VBL in the second direction DR2.

That is, the first anode initialization voltage line VAIL1 may overlap the second light-emitting pixel driver EPD2 and the fifth light-emitting pixel driver EPD5, and the second anode initialization voltage line VAIL2 may overlap the third light-emitting pixel driver EPD3 and the sixth light-emitting pixel driver EPD6.

In accordance with one or more embodiments shown in FIG. 23, the first electrode portion S7 of the seventh transistor T7 of the second light-emitting pixel driver EPD2 and the first electrode portion S7 of the seventh transistor T7 of the third light-emitting pixel driver EPD3 may be connected to each other, and may be electrically connected to the first anode initialization voltage line VAIL1 through a third anode initialization connection hole VAICH3.

Similarly, the first electrode portion S7 of the seventh transistor T7 of the fifth light-emitting pixel driver EPD5, and the first electrode portion S7 of the seventh transistor T7 of the sixth light-emitting pixel driver EPD6, may be connected to each other, and may be electrically connected to the second anode initialization voltage line VAIL2 through a fourth anode initialization connection hole VAICH4.

Accordingly, even if the circuit layer 120 includes the first anode initialization voltage line VAIL1 and the second anode initialization voltage line VAIL2 rather than a single anode initialization voltage line VAIL, the number of wires for transmitting an anode initialization voltage might not be doubled, which makes it possible to reduce or prevent the extent of the reduction in the width of the light-transmitting area TRA.

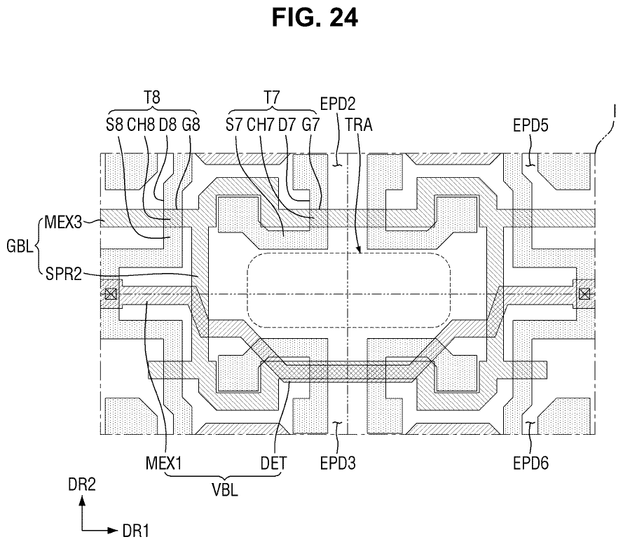

FIG. 24 is a plan view showing part I of FIG. 11 according to one or more embodiments.

The display device 100 of one or more embodiments shown in FIG. 24 is substantially the same as the embodiments shown in FIGS. 1 to 23 except that the second light-emitting pixel driver EPD2 and the third light-emitting pixel driver EPD3 adjacent to each other in the second direction DR2 share one bias control line GBL, so that redundant description will be omitted in the following description.

In accordance with one or more embodiments of FIG. 24, the bias control line GBL may include a third main extension portion MEX3 located adjacent to the first main extension portion MEX1 of the bias voltage line VBL and extending in the first direction DR1, and a second sub-protruding portion SPR2 protruding from the third main extension portion MEX3, extending in the second direction DR2, and intersecting the bias voltage line VBL. The third main extension portion MEX3 may overlap the second light-emitting pixel driver EPD2.

One end of the second sub-protruding portion SPR2 may overlap the third light-emitting pixel driver EPD3. The second sub-protruding portion SPR2 overlapping the third light-emitting pixel driver EPD3, and the second sub-protruding portion SPR2 overlapping the sixth light-emitting pixel driver EPD6, may extend toward each other in the first direction DR1, and may be connected to each other.

That is, the gate electrode G7 of the seventh transistor T7 of the second light-emitting pixel driver EPD2, the gate electrode G8 of the eighth transistor T8 of the second light-emitting pixel driver EPD2, the gate electrode G7 of the seventh transistor T7 of the fifth light-emitting pixel driver EPD5, and the gate electrode G8 of the eighth transistor T8 of the fifth light-emitting pixel driver EPD5 may be provided as parts of the third main extension portion MEX3, and may be connected to each other.

The gate electrode G7 of the seventh transistor T7 of the third light-emitting pixel driver EPD3, the gate electrode G8 of the eighth transistor T8 of the third light-emitting pixel driver EPD3, the gate electrode G7 of the seventh transistor T7 of the sixth light-emitting pixel driver EPD6, and the gate electrode G8 of the eighth transistor T8 of the sixth light-emitting pixel driver EPD6 may be provided as parts of the extension portions of the second sub-protruding portions SPR2 in the first direction DR1, and may be connected to each other.

Accordingly, the second light-emitting pixel driver EPD2 and the third light-emitting pixel driver EPD3 adjacent to each other in the second direction DR2 share one bias control line GBL, so that the number of bias control lines GBL arranged in the main region MA may be reduced by half. Therefore, even if the number of light-emitting pixel drivers EPD is not changed, the light-transmitting areas TRA may secure a wider area in the display area DA by the reduction in the number of bias control lines GBL.

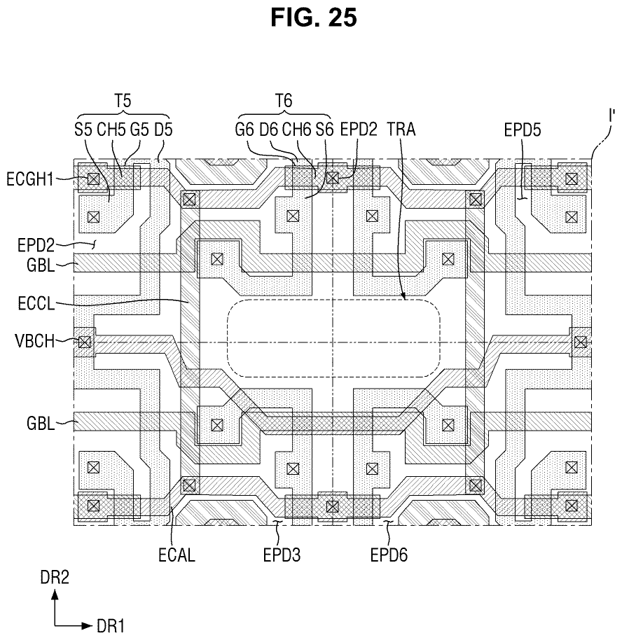

FIG. 25 is a plan view showing part l′ of FIG. 11 according to one or more embodiments.

The display device 100 of one or more embodiments shown in FIG. 25 is substantially the same as the embodiments shown in FIGS. 1 to 24 except that the second light-emitting pixel driver EPD2 and the third light-emitting pixel driver EPD3 adjacent to each other in the second direction DR2 share one emission control line ECL, so that redundant description will be omitted in the following description.

Referring to FIGS. 18 and 21, the gate electrode G5 of the fifth transistor T5 and the gate electrode G6 of the sixth transistor T6 may be located in the same layer as the bias control line GBL.

That is, the first gate conductive layer on the first gate-insulating layer 122 may include the bias control line GBL, the gate electrode G5 of the fifth transistor T5, and the gate electrode G6 of the sixth transistor T6.

The emission control line ECL for transmitting the emission control signal EC to the light-emitting pixel drivers EPD may be located in the same layer as the bias voltage line VBL. That is, the third gate conductive layer on the third gate-insulating layer 125 may include the bias voltage line VBL and the emission control line ECL.

In accordance with one or more embodiments of FIG. 25, the third gate conductive layer may include the bias voltage line VBL, may include the emission control line ECL located adjacent to the bias control line GBL, extending in the first direction DR1, and transmitting the emission control signal EC to the light-emitting pixel drivers EPD, and may include an emission control auxiliary line ECAL extending in the first direction DR1 and spaced apart from the emission control line ECL in the second direction DR2.

The emission control auxiliary line ECAL may be electrically connected to the emission control line ECL through an emission control connection line ECCL extending in the second direction DR2.

The emission control connection line ECCL may intersect the bias control line GBL and the bias voltage line VBL. Accordingly, the emission control connection line ECCL may be located in a gate conductive layer that is different from that of the bias control line GBL and the bias voltage line VBL among the first gate conductive layer, the second gate conductive layer, and the third gate conductive layer.

For example, the bias control line GBL may be located in the first gate conductive layer, the bias voltage line VBL may be located in the third gate conductive layer, and the emission control connection line ECCL may be located in the second gate conductive layer. That is, the second gate conductive layer on the second gate-insulating layer 123 may include the emission control connection line ECCL. However, this is only an example, and the arrangement structure of wires may be changed as long as the condition in which the bias control line GBL, the bias voltage line VBL, and the emission control connection line ECCL are located in different gate conductive layers is satisfied.

The emission control line ECL may overlap the second light-emitting pixel driver EPD2. The emission control auxiliary line ECAL may overlap the third light-emitting pixel driver EPD3. That is, the gate electrode G5 of the fifth transistor T5 of the second light-emitting pixel driver EPD2, and the gate electrode G6 of the sixth transistor T6 of the second light-emitting pixel driver EPD2, may overlap the emission control line ECL. The gate electrode G5 of the fifth transistor T5 of the second light-emitting pixel driver EPD2, and the gate electrode G6 of the sixth transistor T6 of the second light-emitting pixel driver EPD2, may be electrically connected to the emission control line ECL through each connection hole, in one or more embodiments.

Further, the gate electrode G5 of the fifth transistor T5 of the third light-emitting pixel driver EPD3 and the gate electrode G6 of the sixth transistor T6 of the third light-emitting pixel driver EPD3 may overlap the emission control auxiliary line ECAL. In one or more embodiments, the gate electrode G5 of the fifth transistor T5 of the third light-emitting pixel driver EPD3, and the gate electrode G6 of the sixth transistor T6 of the third light-emitting pixel driver EPD3, may be electrically connected to the emission control auxiliary line ECAL through each connection hole, and may be electrically connected to the emission control line ECL through the emission control auxiliary line ECAL and the emission control connection line ECCL.

Accordingly, the second light-emitting pixel driver EPD2 and the third light-emitting pixel driver EPD3 adjacent to each other in the second direction DR2 share one emission control line ECL, so that the number of emission control lines ECL arranged in the main region MA may be reduced by half. Therefore, even if the number of light-emitting pixel drivers EPD is not changed, the light-transmitting areas TRA may secure a wider area in the display area DA by the reduction in the number of emission control lines ECL.

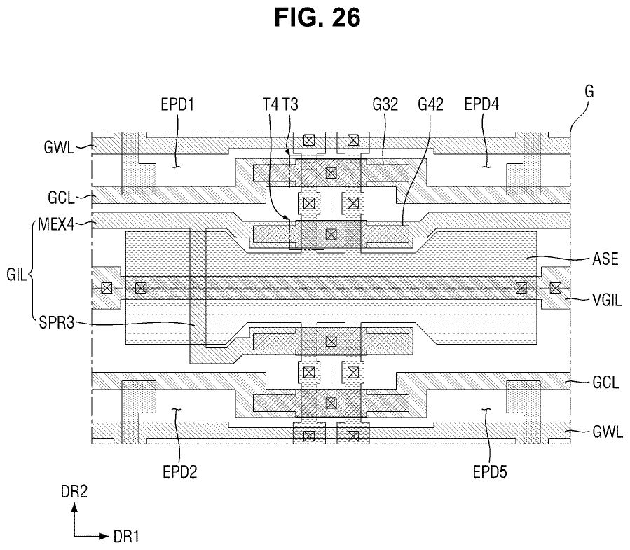

FIG. 26 is a plan view showing a first semiconductor layer, a second semiconductor layer, a first gate conductive layer, a second gate conductive layer, and a third gate conductive layer in part G of FIG. 11 according to one or more embodiments.

The display device 100 of one or more embodiments shown in FIG. 26 is substantially the same as the embodiments shown in FIGS. 1 to 25 except that the second light-emitting pixel driver EPD2 and the first light-emitting pixel driver EPD1 adjacent to each other in the second direction DR2 share one scan initialization line GIL, so that redundant description will be omitted in the following description.

Referring to FIGS. 13 and 14, the first gate conductive layer on the first gate-insulating layer 122 may include the scan initialization line GIL for transmitting the scan initialization signal GI to the light-emitting pixel drivers EPD.

The first gate conductive layer may further include the scan write line GWL for transmitting the scan write signal GW to the light-emitting pixel drivers EPD. The second gate conductive layer on the second gate-insulating layer 123 may include the gate initialization voltage line VGIL and the gate control line GCL. The scan initialization line GIL, the scan write line GWL, the gate initialization voltage line VGIL, and the gate control line GCL may each extend in the first direction DR1. The third gate conductive layer on the third gate-insulating layer 125 may include the second gate electrode G32 of the third transistor T3 and the second gate electrode G42 of the fourth transistor T4.

In accordance with one or more embodiments of FIG. 26, the scan initialization line GIL may include a fourth main extension portion MEX4 located adjacent to the gate initialization voltage line VGIL and extending in the first direction DR1, and a third sub-protruding portion SPR3 protruding from the fourth main extension portion MEX4, extending in the second direction DR2, and intersecting the gate initialization voltage line VGIL. The fourth main extension portion MEX4 may overlap the first light-emitting pixel driver EPD1.

One end of the third sub-protruding portion SPR3 may overlap the second light-emitting pixel driver EPD2. That is, the first gate electrode G41 of the fourth transistor T4 of the first light-emitting pixel driver EPD1 may be provided as a part of the fourth main extension portion MEX4, and the second gate electrode G42 of the fourth transistor T4 of the first light-emitting pixel driver EPD1 may overlap the fourth main extension portion MEX4.

The first gate electrode G41 of the fourth transistor T4 of the second light-emitting pixel driver EPD2 may be provided as a part of the third sub-protruding portion SPR3, and the second gate electrode G42 of the fourth transistor T4 of the second light-emitting pixel driver EPD2 may overlap the third sub-protruding portion SPR3.

Accordingly, the second light-emitting pixel driver EPD2 and the first light-emitting pixel driver EPD1 adjacent to each other in the second direction DR2 share one scan initialization line GIL, so that the number of scan initialization lines GIL arranged in the main region MA may be reduced by half. Therefore, even if the number of scan initialization lines GIL is not changed, the light-transmitting areas TRA may secure a wider area in the display area DA by the reduction in the number of scan initialization lines GIL.

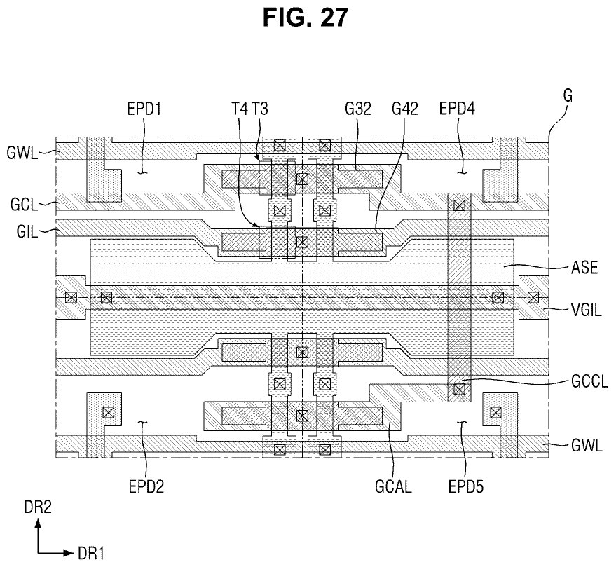

FIG. 27 is a plan view showing a first semiconductor layer, a second semiconductor layer, a first gate conductive layer, a second gate conductive layer, and a third gate conductive layer in part G of FIG. 11 according to one or more embodiments.

The display device 100 of one or more embodiments shown in FIG. 27 is substantially the same as the embodiments shown in FIGS. 1 to 26 except that the second light-emitting pixel driver EPD2 and the third light-emitting pixel driver EPD3 adjacent to each other in the second direction DR2 share one gate control line GCL, so that redundant description will be omitted in the following description.

Referring to FIGS. 13 and 14, the first gate conductive layer on the first gate-insulating layer 122 may include the scan initialization line GIL for transmitting the scan initialization signal GI to the light-emitting pixel drivers EPD, and the scan write line GWL for transmitting the scan write signal GW to the light-emitting pixel drivers EPD.

In accordance with one or more embodiments of FIG. 27, the second gate conductive layer on the second gate-insulating layer 123 may include the gate initialization voltage line VGIL, the gate control line GCL located adjacent to the scan initialization line GIL, extending in the first direction DR1, and transmitting the gate control signal GC to the light-emitting pixel drivers EPD, and a gate control auxiliary line GCAL extending in the first direction DR1 and spaced apart from the gate control line GCL in the second direction DR2.

The gate control auxiliary line GCAL may be electrically connected to the gate control line GCL through a gate control connection line GCCL extending in the second direction DR2. The gate control connection line GCCL may intersect the scan initialization line GIL and the gate initialization voltage line VGIL. Accordingly, the gate control connection line GCCL may be located in a gate conductive layer different from that of the scan initialization line GIL and the gate initialization voltage line VGIL, which may be located among respective ones of the first to third gate conductive layers. For example, the scan initialization line GIL may be located in the first gate conductive layer, the gate initialization voltage line VGIL may be located in the second gate conductive layer, and the gate control connection line GCCL may be located in the third gate conductive layer. That is, the third gate conductive layer on the third gate-insulating layer 125 may include the gate control connection line GCCL.

However, this is only an example, and the arrangement structure of wires may be changed as long as the condition in which the scan initialization line GIL, the gate initialization voltage line VGIL, and the gate control connection line GCCL are located in different gate conductive layers is satisfied.

Further, the third gate conductive layer on the third gate-insulating layer 125 may include the second gate electrode G32 of the third transistor T3, and the second gate electrode G42 of the fourth transistor T4.

The gate control line GCL may overlap the first light-emitting pixel driver EPD1. The gate control auxiliary line GCAL may overlap the second light-emitting pixel driver EPD2. That is, the first gate electrode G31 of the third transistor T3 of the first light-emitting pixel driver EPD1 may be provided as a part of the gate control line GCL, and the second gate electrode G32 of the third transistor T3 of the first light-emitting pixel driver EPD1 may overlap the gate control line GCL.

The first gate electrode G31 of the third transistor T3 of the second light-emitting pixel driver EPD2 may be provided as a part of the gate control auxiliary line GCAL, and the second gate electrode G32 of the third transistor T3 of the second light-emitting pixel driver EPD2 may overlap the gate control auxiliary line GCAL. Accordingly, the second light-emitting pixel driver EPD2 and the first light-emitting pixel driver EPD1 adjacent to each other in the second direction DR2 share one gate control line GCL, so that the number of gate control lines GCL arranged in the main region MA may be reduced by half. Therefore, even if the number of light-emitting pixel drivers EPD is not changed, the light-transmitting areas TRA may secure a wider area in the display area DA by the reduction in the number of gate control lines GCL.

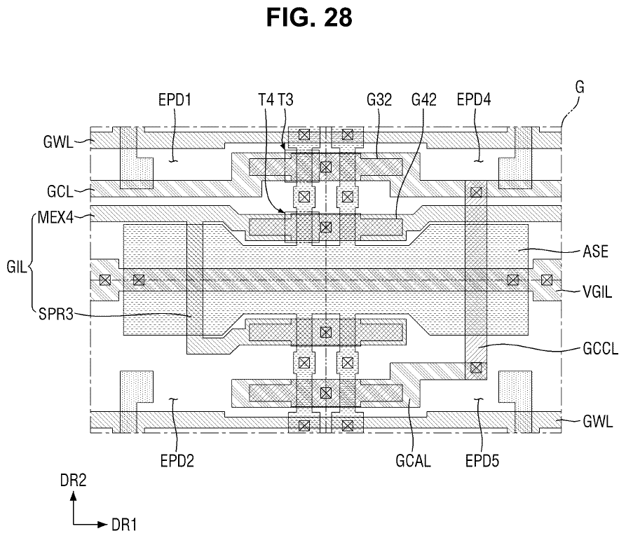

FIG. 28 is a plan view showing a first semiconductor layer, a second semiconductor layer, a first gate conductive layer, a second gate conductive layer, and a third gate conductive layer in part G of FIG. 11 according to one or more embodiments.

In accordance with one or more embodiments shown in FIG. 28, the second light-emitting pixel driver EPD2 and the first light-emitting pixel driver EPD1 adjacent to each other in the second direction DR2 may share one scan initialization line GIL and one gate control line GCL. That is, the one or more embodiments corresponding to FIG. 28 is a structure in which the one or more embodiments corresponding to FIG. 26 and the one or more embodiments corresponding to FIG. 27 are merged, so that redundant description will be omitted in the following description.

Accordingly, even if the number of light-emitting pixel drivers EPD is not changed, the light-transmitting areas TRA in the display area DA may secure a wider area by the reduction in the number of scan initialization lines GIL and the number of gate control lines GCL.

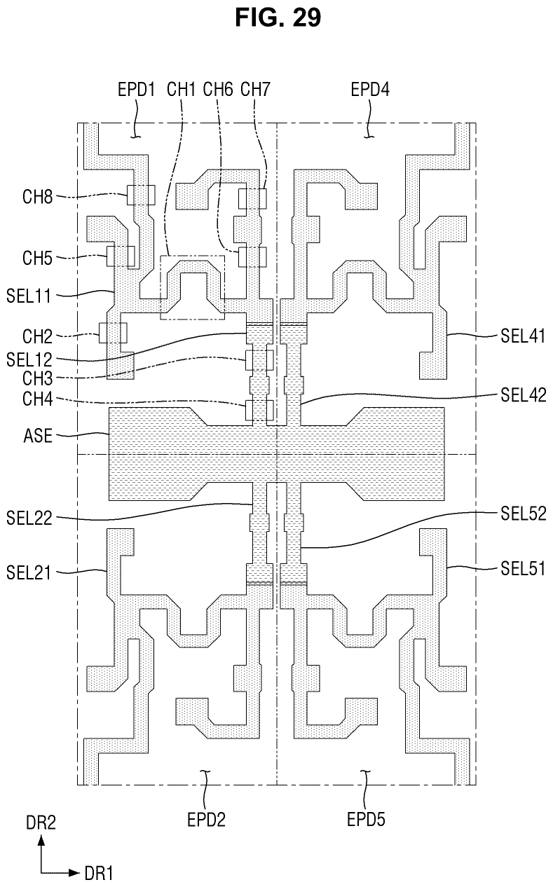

FIG. 29 is a plan view showing a first semiconductor layer and a second semiconductor layer of each of a first light-emitting pixel driver, a second light-emitting pixel driver, a fourth light-emitting pixel driver, and a fifth light-emitting pixel driver according to embodiments.

As shown in FIG. 29, in accordance with embodiments, a first semiconductor layer SEL11 on the substrate 110 may include respective channel portions CH1, CH2, CH5, CH6, CH7, and CH8 of the first transistor T1, the second transistor T2, the fifth transistor T5, the sixth transistor T6, the seventh transistor T7, and the eighth transistor T8, and the first electrode portion and the second electrode portion connected to both ends thereof.

A second semiconductor layer SEL12 may include the channel portions CH3 and CH4 of the third transistor T3 and the fourth transistor T4, and the first electrode portion and the second electrode portion connected to both ends thereof.

Referring to FIG. 29, in the circuit layer 120 of the display device 100 according to embodiments, a first semiconductor layer SEL11 and a second semiconductor layer SEL12 of the first light-emitting pixel driver EPD1 may be symmetrical with a first semiconductor layer SEL41 and a second semiconductor layer SEL42 of the fourth light-emitting pixel driver EPD4 with respect to the boundary between the first light-emitting pixel driver EPD1 and the fourth light-emitting pixel driver EPD4 adjacent in the first direction DR1.

Further, in accordance with embodiments, the first semiconductor layer SEL11 and the second semiconductor layer SEL12 of the first light-emitting pixel driver EPD1 may be symmetrical with a first semiconductor layer SEL21 and a second semiconductor layer SEL22 of the second light-emitting pixel driver EPD2 with respect to the boundary between the first light-emitting pixel driver EPD1 and the second light-emitting pixel driver EPD2 adjacent in the second direction DR2, which in turn may be symmetrical with a first semiconductor layer SEL51 and a second semiconductor layer SEL52 of the fifth light-emitting pixel driver EPD5 with respect to the boundary between the second light-emitting pixel driver EPD2 and the fifth light-emitting pixel driver EPD5 adjacent in the first direction DR1.

Accordingly, the implementation of the structure in which at least one of the bias voltage line VBL, the anode initialization voltage line VAIL, the bias control line GBL, the emission control line ECL, the gate initialization voltage line VGIL, the scan initialization line GIL, or the gate control line GCL adjacent to the boundary between the light-emitting pixel drivers EPD adjacent in the second direction DR2 and extending in the first direction DR1 are shared by the light-emitting pixel drivers EPD adjacent in the second direction DR2 may be facilitated.

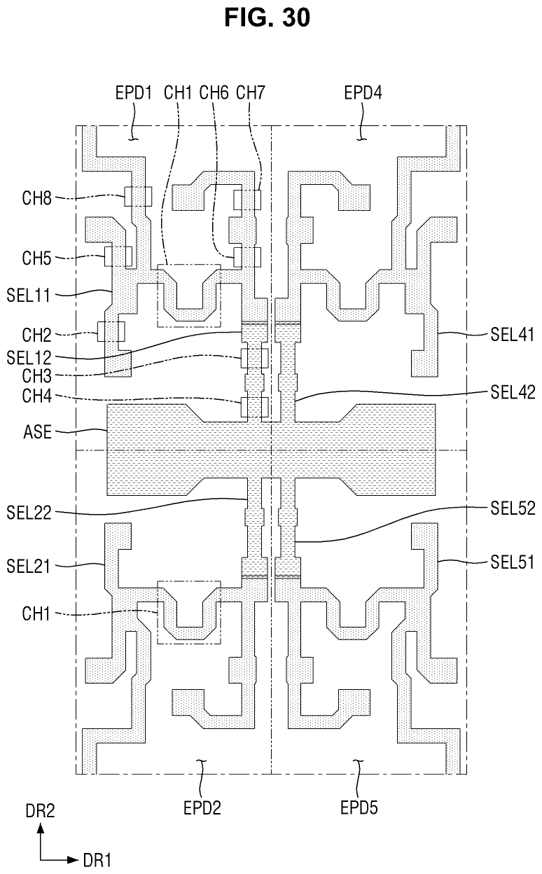

FIG. 30 is a plan view showing a first semiconductor layer and a second semiconductor layer of each of a first light-emitting pixel driver, a second light-emitting pixel driver, a fourth light-emitting pixel driver, and a fifth light-emitting pixel driver according to one or more embodiments.

The display device 100 according to one or more embodiments shown in FIG. 30 is substantially the same as the embodiments of FIGS. 1 to 29 except that the channel portion CH1 of the first transistor T1 of the first light-emitting pixel driver EPD1 is identical to the channel portion CH1 of the first transistor T1 of the second light-emitting pixel driver EPD2 with respect to the boundary between the first light-emitting pixel driver EPD1 and the second light-emitting pixel driver EPD2 adjacent in the second direction DR2, so that redundant description will be omitted in the following description.

For example, in all the light-emitting pixel drivers EPD, the channel portion CH1 of the first transistor T1 may be similarly U-shaped and convex on one side (lower side in FIG. 30) in the second direction DR2. However, the illustration in FIG. 30 is only an example, and the channel portion CH1 of the first transistor T1 may be modified into other forms.

Accordingly, during the crystallization process of the first semiconductor layers SEL11, SEL21, SEL41, and SEL51 using a laser, laser may be similarly irradiated to the channel portion CH1 of the first transistor T1 of each of the light-emitting pixel drivers EPD, so that the uniformity of semiconductor characteristics of the channel portion CH1 of the first transistor T1 may be improved. Accordingly, defects, such as stains may be reduced, which makes it possible to improve the display quality of the display device 100.

However, the effects of the present disclosure are not restricted to the one set forth herein. The above and other effects of the present disclosure will become more apparent to one of daily skill in the art to which the present disclosure pertains by referencing the claims, with functional equivalents thereof to be included therein.

What is claimed is:

1. A display device comprising:
a substrate comprising a display area having emission areas, and a non-display area around the display area;
an element layer above the substrate, and comprising light-emitting elements respectively in the emission areas; and
a circuit layer between the substrate and the element layer, and comprising:
light-emitting pixel drivers respectively electrically connected to the light-emitting elements, arranged side by side with each other in a first direction and in a second direction, and comprising a first light-emitting pixel driver and a second light-emitting pixel driver adjacent to each other in the second direction;
data lines extending in the second direction for transmitting data signals to the light-emitting pixel drivers;
two first bypass auxiliary lines extending in the first direction, adjacent to each other in the second direction, and respectively electrically connected to two first data lines of the data lines that are adjacent to the non-display area;
a second bypass auxiliary line extending in the second direction, electrically connected to the first bypass auxiliary line, and paired with a second data line of the data lines that is spaced further from the non-display area than the first data line in the first direction; and
a gate initialization voltage line adjacent to one of the first bypass auxiliary lines in the second direction at a boundary between the first light-emitting pixel driver and the second light-emitting pixel driver, and extending in the first direction for transmitting a gate initialization voltage to the light-emitting pixel drivers.

2. The display device of claim 1, wherein the first light-emitting pixel driver and the second light-emitting pixel driver are electrically connected to the gate initialization voltage line.

3. The display device of claim 1, further comprising a display-driving circuit for transmitting the data signals to the data lines,
wherein the circuit layer further comprises data supply lines in the non-display area, and electrically connected between the data lines and the display-driving circuit,
wherein a bypass area on one side of the display area comprises a bypass middle area, a first bypass side area parallel to the bypass middle area in the first direction and in contact with the non-display area, and a second bypass side area between the bypass middle area and the first bypass side area,
wherein the first data lines are in the first bypass side area,
wherein the second data line is in the second bypass side area,
wherein a first data supply line of the data supply lines is electrically connected to one of the first data lines through one of the first bypass auxiliary lines and the second bypass auxiliary line, and
wherein a second data supply line of the data supply lines is directly electrically connected to the second data line.

4. The display device of claim 2, wherein the circuit layer further comprises a bias voltage line extending in the first direction for transmitting a bias voltage to the light-emitting pixel drivers,
wherein the light-emitting pixel drivers further comprise a third light-emitting pixel driver adjacent to the second light-emitting pixel driver in the second direction, and
wherein the second light-emitting pixel driver and the third light-emitting pixel driver are electrically connected to the bias voltage line adjacent to a boundary between the second light-emitting pixel driver and the third light-emitting pixel driver.

5. The display device of claim 4, wherein the light-emitting pixel drivers further comprise:
a fourth light-emitting pixel driver adjacent to the first light-emitting pixel driver in the first direction;
a fifth light-emitting pixel driver adjacent to the second light-emitting pixel driver in the first direction; and
a sixth light-emitting pixel driver adjacent to the third light-emitting pixel driver in the first direction,
wherein the fourth light-emitting pixel driver and the fifth light-emitting pixel driver are electrically connected to the gate initialization voltage line, and
wherein the bias voltage line comprises:
a first main extension portion extending in the first direction; and
a bypass portion connected to the first main extension portion, and bypassing a light-transmitting area comprising contact points at which the second light-emitting pixel driver, the third light-emitting pixel driver, the fifth light-emitting pixel driver, and the sixth light-emitting pixel driver contact each other in the display area.

6. The display device of claim 4, wherein the circuit layer has a multi-layer structure comprising:
a first semiconductor layer above the substrate;
a first gate-insulating layer covering the first semiconductor layer;
a first gate conductive layer above the first gate-insulating layer;
a second gate-insulating layer covering the first gate conductive layer;
a second gate conductive layer above the second gate-insulating layer;
a first interlayer insulating layer covering the second gate conductive layer;
a second semiconductor layer above the first interlayer insulating layer;
a third gate-insulating layer covering the second semiconductor layer;
a third gate conductive layer above the third gate-insulating layer;
a second interlayer insulating layer covering the third gate conductive layer;
a first source-drain conductive layer above the second interlayer insulating layer;
a first planarization layer covering the first source-drain conductive layer;
a second source-drain conductive layer above the first planarization layer; and
a second planarization layer covering the second source-drain conductive layer,
wherein the first semiconductor layer and the second semiconductor layer in the first light-emitting pixel driver are symmetrical with the first semiconductor layer and the second semiconductor layer in the second light-emitting pixel driver with respect to the boundary between the first light-emitting pixel driver and the second light-emitting pixel driver.

7. The display device of claim 6, wherein the first semiconductor layer and the second semiconductor layer in the first light-emitting pixel driver are symmetrical with the first semiconductor layer and the second semiconductor layer in the third light-emitting pixel driver with respect to a boundary between the first light-emitting pixel driver and the third light-emitting pixel driver.

8. The display device of claim 6, wherein the light-emitting pixel drivers comprise:
a first transistor electrically connected between a first node and a second node;
a pixel capacitor electrically connected between a first power line for transmitting a first power and a third node;
a second transistor electrically connected between a respective one of the data lines and the first node;
a third transistor electrically connected between the second node and the third node;
a fourth transistor electrically connected between the gate initialization voltage line and the third node;
a fifth transistor electrically connected between the first power line and the first node;
a sixth transistor electrically connected between the second node and a fourth node;
a seventh transistor electrically connected between an anode initialization voltage line for transmitting an anode initialization voltage and the fourth node; and
an eighth transistor electrically connected between the bias voltage line and the first node,
wherein the first node is electrically connected to a first electrode of the first transistor,
wherein the second node is electrically connected to a second electrode of the first transistor,
wherein the third node is electrically connected to a gate electrode of the first transistor,
wherein the fourth node is electrically connected to one of the light-emitting elements,
wherein the first transistor, the second transistor, the third transistor, the fourth transistor, the fifth transistor, the sixth transistor, the seventh transistor, and the eighth transistor comprise a gate electrode, a channel portion overlapping the gate electrode, and a first electrode portion and a second electrode portion connected to respective sides of the channel portion,
wherein the third transistor and the fourth transistor further comprises an auxiliary gate electrode overlapping the gate electrode and the channel portion,
wherein the first semiconductor layer comprises a channel portion, a first electrode portion, and a second electrode portion of the first transistor, the second transistor, the fifth transistor, the sixth transistor, the seventh transistor, and the eighth transistor, and
wherein the second semiconductor layer comprises a channel portion, a first electrode portion, and a second electrode portion of the third transistor and the fourth transistor.

9. The display device of claim 8, wherein the channel portion of the first transistor of the first light-emitting pixel driver is substantially identical to the channel portion of the first transistor of the second light-emitting pixel driver.

10. The display device of claim 8, wherein the third transistor is configured to be turned on by a gate control signal of a gate control line,
wherein the fourth transistor is configured to be turned on by a scan initialization signal of a scan initialization line,
wherein the fifth transistor and the sixth transistor are configured to be turned on by an emission control signal of an emission control line, and
wherein the seventh transistor is configured to be turned on by a bias control signal of a bias control line,
wherein the first light-emitting pixel driver and the second light-emitting pixel driver share at least one of the gate initialization voltage line, the scan initialization line, or the gate control line, and
wherein the second light-emitting pixel driver and the third light-emitting pixel driver share at least one of the anode initialization voltage line, the bias control line, or the emission control line.

11. The display device of claim 8, wherein the second gate conductive layer comprises the gate initialization voltage line,
wherein the second semiconductor layer further comprises an auxiliary electrode portion connected to the second electrode portion of the fourth transistor, and extending in the first direction,
wherein the first source-drain conductive layer comprises the first bypass auxiliary line,
wherein the auxiliary electrode portion of the first light-emitting pixel driver and the auxiliary electrode portion of the second light-emitting pixel driver are connected to each other, and electrically connected to the gate initialization voltage line through a gate initialization connection electrode, and
wherein the two first bypass auxiliary lines adjacent to the boundary between the first light-emitting pixel driver and the second light-emitting pixel driver overlaps at least one of the auxiliary electrode portion of the first light-emitting pixel driver or the auxiliary electrode portion of the second light-emitting pixel driver.

12. The display device of claim 11, wherein one of two second bypass auxiliary lines adjacent to the boundary between the first light-emitting pixel driver and the second light-emitting pixel driver is adjacent to one side of the gate initialization voltage line in the second direction, and
wherein another of the two second bypass auxiliary lines is adjacent to another side of the gate initialization voltage line in the second direction.

13. The display device of claim 11, wherein two second bypass auxiliary lines adjacent to the boundary between the first light-emitting pixel driver and the second light-emitting pixel driver are arranged side by side on one side of the gate initialization voltage line in the second direction.

14. A display device comprising:
a substrate comprising a display area having emission areas, and a non-display area around the display area;
an element layer above the substrate, and comprising light-emitting elements respectively in the emission areas; and
a circuit layer between the substrate and the element layer, and comprising:
light-emitting pixel drivers respectively electrically connected to the light-emitting elements of the element layer, arranged side by side with each other in a first direction and a second direction, and comprising a first transistor for generating a driving current of the light-emitting element;
data lines extending in the second direction for transmitting data signals to the light-emitting pixel drivers;
a first bypass auxiliary line extending in the first direction, and electrically connected to a first data line of the data lines that is adjacent to the non-display area in the first direction;
a second bypass auxiliary line extending in the second direction, paired with a second data line of the data lines that is spaced further from the non-display area than the first data line in the first direction, and electrically connected to the first bypass auxiliary line; and
a first power line for transmitting a first power to the light-emitting pixel drivers, and comprising:
a first power main line extending in the first direction, overlapping a gate electrode of the first transistor, and overlapping the first bypass auxiliary line; and
a first power sub-line extending in the second direction and electrically connected to the first power main line.

15. The display device of claim 14, wherein the light-emitting pixel drivers comprise a first light-emitting pixel driver, a second light-emitting pixel driver, and a third light-emitting pixel driver arranged in the second direction,
wherein the first light-emitting pixel driver and the second light-emitting pixel driver are electrically connected to a gate initialization voltage line adjacent to a boundary between the first light-emitting pixel driver and the second light-emitting pixel driver, and
wherein the second light-emitting pixel driver and the third light-emitting pixel driver are electrically connected to a bias voltage line adjacent to a boundary between the second light-emitting pixel driver and the third light-emitting pixel driver.

16. The display device of claim 15, wherein the light-emitting pixel drivers further comprise:
a fourth light-emitting pixel driver adjacent to the first light-emitting pixel driver in the first direction;
a fifth light-emitting pixel driver adjacent to the second light-emitting pixel driver in the first direction; and
a sixth light-emitting pixel driver adjacent to the third light-emitting pixel driver in the first direction,
wherein the fourth light-emitting pixel driver and the fifth light-emitting pixel driver are electrically connected to the gate initialization voltage line, and
wherein the bias voltage line comprises:
a first main extension portion extending in the first direction; and
a bypass portion connected to the first main extension portion, and bypassing a light-transmitting area comprising contact points at which the second light-emitting pixel driver, the third light-emitting pixel driver, the fifth light-emitting pixel driver, and the sixth light-emitting pixel driver contact each other in the display area.

17. The display device of claim 16, wherein the circuit layer has a multi-layer structure comprising:
a first semiconductor layer above the substrate;
a first gate-insulating layer covering the first semiconductor layer;
a first gate conductive layer above the first gate-insulating layer;
a second gate-insulating layer covering the first gate conductive layer;
a second gate conductive layer above the second gate-insulating layer;
a first interlayer insulating layer covering the second gate conductive layer;
a second semiconductor layer above the first interlayer insulating layer;
a third gate-insulating layer covering the second semiconductor layer;
a third gate conductive layer above the third gate-insulating layer;
a second interlayer insulating layer covering the third gate conductive layer;
a first source-drain conductive layer above the second interlayer insulating layer;
a first planarization layer covering the first source-drain conductive layer;
a second source-drain conductive layer above the first planarization layer; and
a second planarization layer covering the second source-drain conductive layer,
wherein the first transistor is electrically connected between a first node and a second node.

18. The display device of claim 17, wherein the light-emitting pixel drivers further comprise:
a pixel capacitor electrically connected between the first power line and a third node;
a second transistor electrically connected between one of the data lines and the first node;
a third transistor electrically connected between the second node and the third node;
a fourth transistor electrically connected between the gate initialization voltage line and the third node;
a fifth transistor electrically connected between the first power line and the first node;
a sixth transistor electrically connected between the second node and a fourth node;
a seventh transistor electrically connected between an anode initialization voltage line for transmitting an anode initialization voltage and the fourth node; and
an eighth transistor electrically connected between the bias voltage line and the first node,
wherein the first node is electrically connected to a first electrode of the first transistor,
wherein the second node is electrically connected to a second electrode of the first transistor,
wherein the third node is electrically connected to a gate electrode of the first transistor,
wherein the fourth node is electrically connected to one of the light-emitting elements,
wherein the first transistor, the second transistor, the third transistor, the fourth transistor, the fifth transistor, the sixth transistor, the seventh transistor, and the eighth transistor comprise a gate electrode, a channel portion overlapping the gate electrode, and a first electrode portion and a second electrode portion connected to respective sides of the channel portion,
wherein the third transistor and the fourth transistor further comprises an auxiliary gate electrode overlapping the gate electrode and the channel portion,
wherein the first semiconductor layer comprises a channel portion, a first electrode portion, and a second electrode portion of the first transistor, the second transistor, the fifth transistor, the sixth transistor, the seventh transistor, and the eighth transistor, and
wherein the second semiconductor layer comprises a channel portion, a first electrode portion, and a second electrode portion of the third transistor and the fourth transistor.

19. The display device of claim 18, wherein the third transistor is configured to be turned on by a gate control signal of a gate control line,
wherein the fourth transistor is configured to be turned on by a scan initialization signal of a scan initialization line,
wherein the fifth transistor and the sixth transistor are configured to be turned on by an emission control signal of an emission control line,
wherein the seventh transistor is configured to be turned on by a bias control signal of a bias control line,
wherein the first light-emitting pixel driver and the second light-emitting pixel driver share at least one of the gate initialization voltage line, the scan initialization line, or the gate control line, and
wherein the second light-emitting pixel driver and the third light-emitting pixel driver share at least one of the anode initialization voltage line, the bias control line, or the emission control line.

20. The display device of claim 18, wherein the second gate conductive layer comprises the first power main line,
wherein the first source-drain conductive layer comprises the first bypass auxiliary line, and a first power connection line electrically connected to the first power main line and the first power sub-line, and spaced apart from the first bypass auxiliary line, and
wherein the second source-drain conductive layer comprises the first power sub-line.
